(19) United States
(12) Patent Application Publication
(10) Pub. No.: US 2026/0173443 A1
(43) Pub. Date: Jun. 18, 2026

(54) SEMICONDUCTOR DEVICE

(71) Applicant: ROHM CO., LTD., Kyoto-shi (JP)

(72) Inventors: Takui SAKAGUCHI, Kyoto-shi (JP); Seigo MORI, Kyoto-shi (JP); Kenji AOKI, Kyoto-shi (JP)

(73) Assignee: ROHM CO., LTD., Kyoto-shi (JP)

(21) Appl. No.: 19/530,432

(22) Filed: Feb. 5, 2026

Related U.S. Application Data
(63) Continuation of application No. PCT/JP2024/028789, filed on Aug. 9, 2024.

(30) Foreign Application Priority Data
Aug. 15, 2023 (JP) 2023-132222

(51) Int. Cl. H10D 30/66; H10D 62/10; H10D 62/832

(52) U.S. Cl. CPC H10D 30/66; H10D 62/127; H10D 62/8325

(57) ABSTRACT

A semiconductor device includes a chip that has a main surface, a body region that is formed in a surface layer portion of the main surface, gate electrodes that are arranged on both sides of the body region on the main surface, and a connection electrode that is formed in a region between the gate electrodes on the main surface so as to overlap the body region in a thickness direction.

### CROSS-REFERENCE TO RELATED APPLICATIONS

The present application is a bypass continuation of International Patent Application No. PCT/JP2024/028789, filed on Aug. 9, 2024, which claims priority to Japanese Patent Application No. 2023-132222, filed on Aug. 15, 2023 in the Japan Patent Office, and the entire contents of these applications are hereby incorporated herein by reference.

### BACKGROUND

### 1. Field of the Disclosure

The present disclosure relates to a semiconductor device.

### 2. Description of the Related Art

WO2016/143099A1 discloses an SiC power MISFET including a plurality of p-type body regions, and a gate electrode. In FIG. 1 and FIG. 3 of the patent document, the p-type body regions are formed at intervals, and the gate electrode is formed in a grid pattern and surrounds the p-type body regions. In FIG. 4 of the patent document, the p-type body regions extend in one direction, and the gate electrodes extend in the one direction in regions between the adjacent p-type body regions.

### BRIEF DESCRIPTION OF DRAWINGS

FIG. 1 is a plan view illustrating a semiconductor device according to one embodiment.

FIG. 2 is a sectional view taken along line II-II shown in FIG. 1.

FIG. 3 is a plan view illustrating a layout example of the first main surface.

FIG. 4 is an enlarged plan view illustrating one main portion of an active region together with a planar structure according to a first layout example.

FIG. 5 is a sectional view taken along line V-V shown in FIG. 4.

FIG. 6 is a sectional view taken along line VI-VI shown in FIG. 4.

FIG. 7 is a sectional view taken along line VII-VII shown in FIG. 4.

FIG. 8 is an enlarged sectional view illustrating one region shown in FIG. 5.

FIG. 9 is an enlarged sectional view illustrating one region shown in FIG. 7.

FIG. 10 is a cutaway perspective view illustrating one main portion of the active region.

FIG. 11 is a sectional view taken along line XI-XI shown in FIG. 1.

FIG. 12 is an enlarged sectional view illustrating one region shown in FIG. 11.

FIG. 13 is an enlarged plan view illustrating one main portion of the active region together with the planar structure according to a second layout example.

FIG. 14 is a sectional view illustrating the semiconductor device according to a first modified example.

FIG. 15 is a sectional view illustrating the semiconductor device according to a second modified example.

FIG. 16 is a sectional view illustrating the semiconductor device according to a third modified example.

### DETAILED DESCRIPTION OF THE PREFERRED EMBODIMENTS

Hereinafter, specific embodiments will be described in detail with reference to the accompanying drawings. All of the accompanying drawings are schematic views and thus are not precisely drawn and are not always matched in relative positional relationships, reduced scales, ratios, angles, etc. Identical reference signs are given to corresponding structures among the attached drawings, and duplicate descriptions thereof shall be omitted or simplified. For the structures, whose description have been omitted or simplified, the description given before the omission or simplification shall apply.

When the wording “substantially” is used in this Description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element, and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

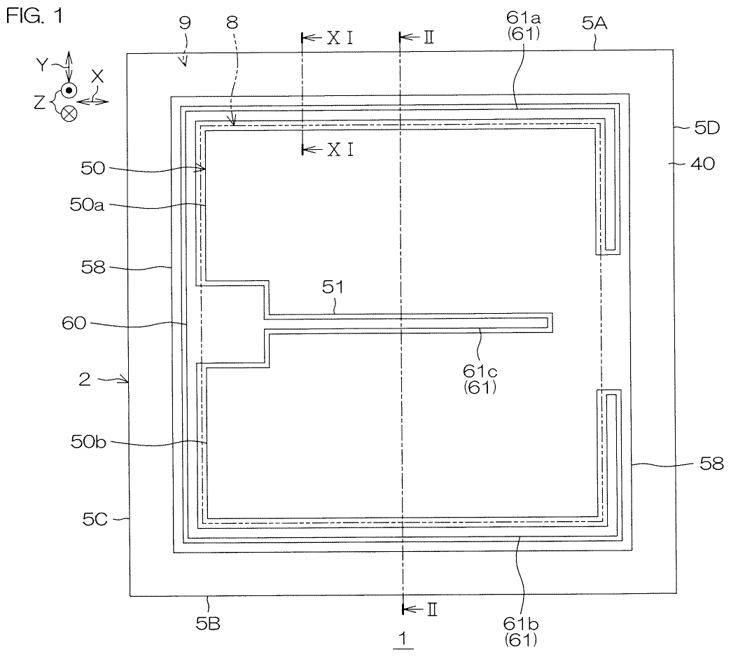

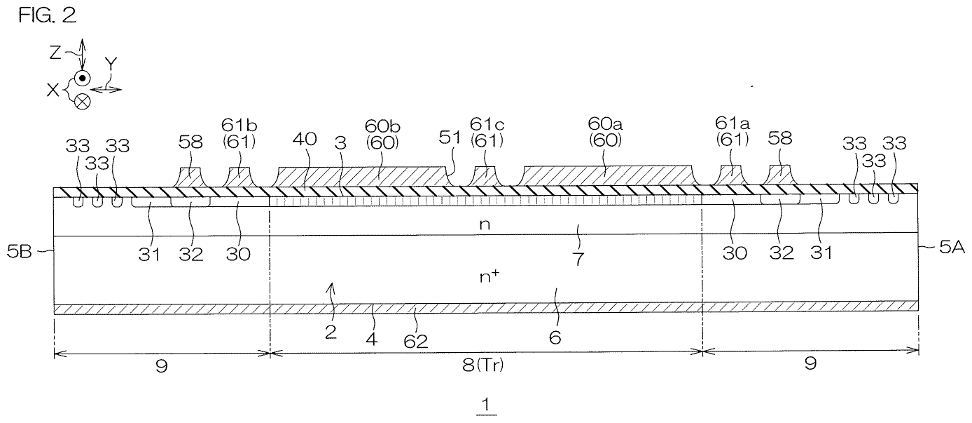

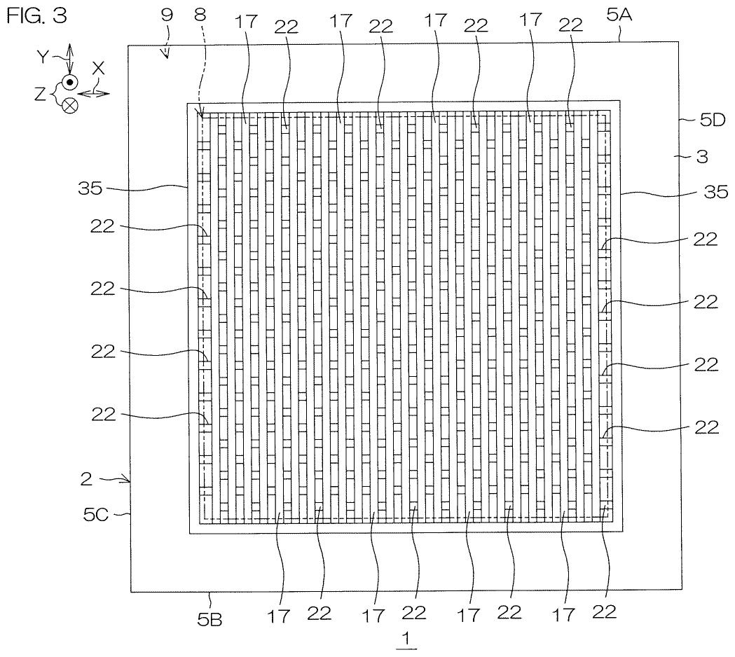

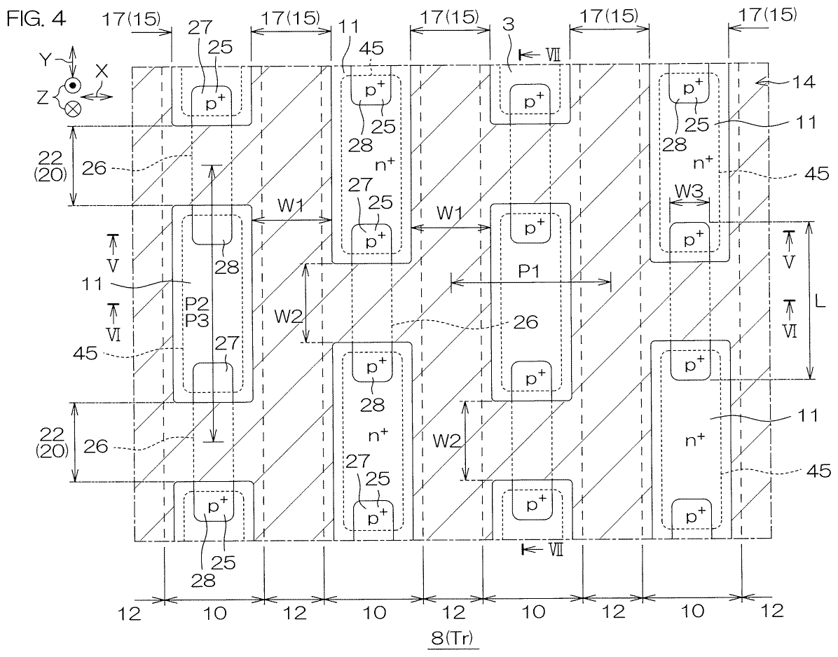

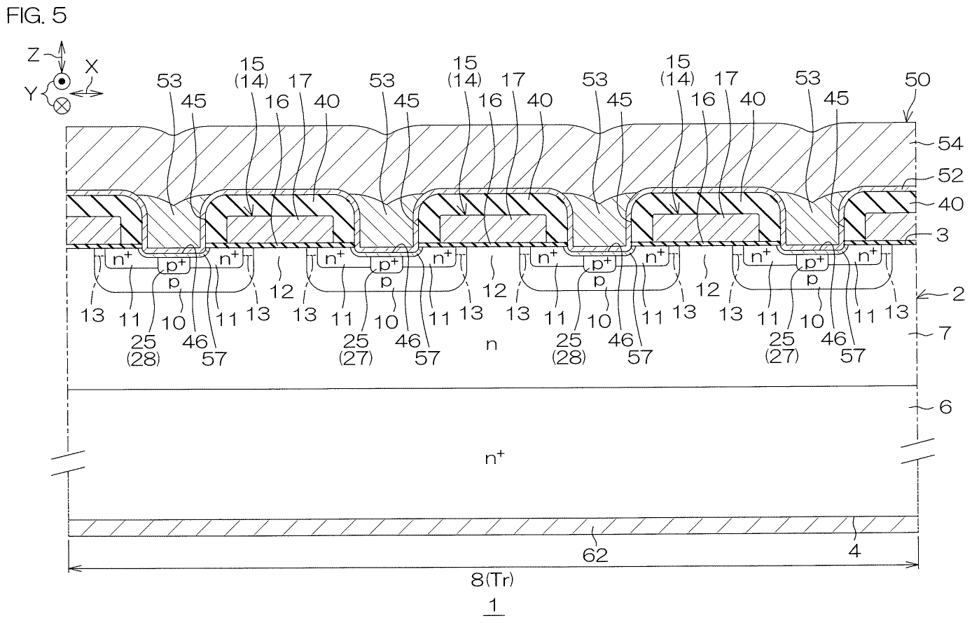

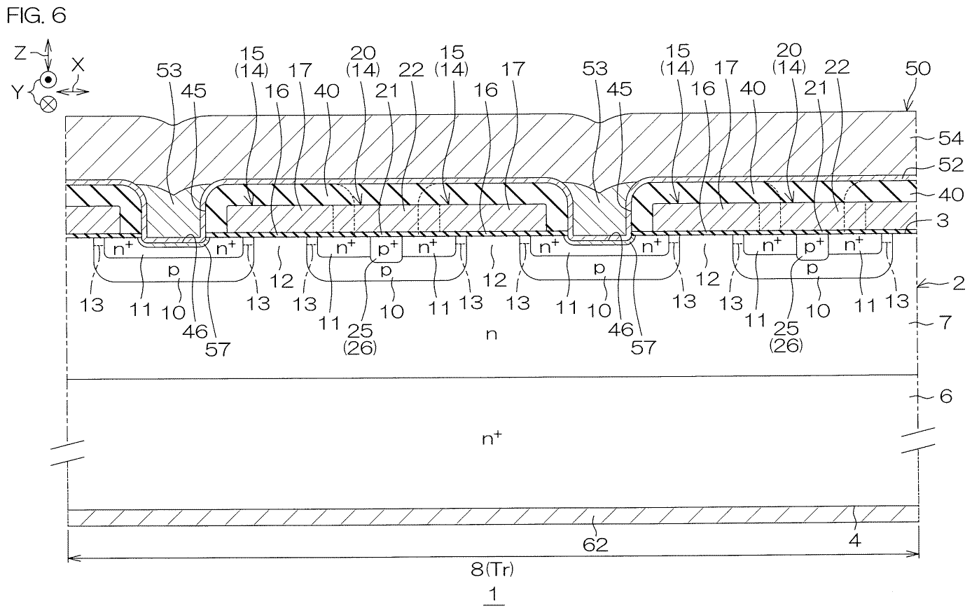

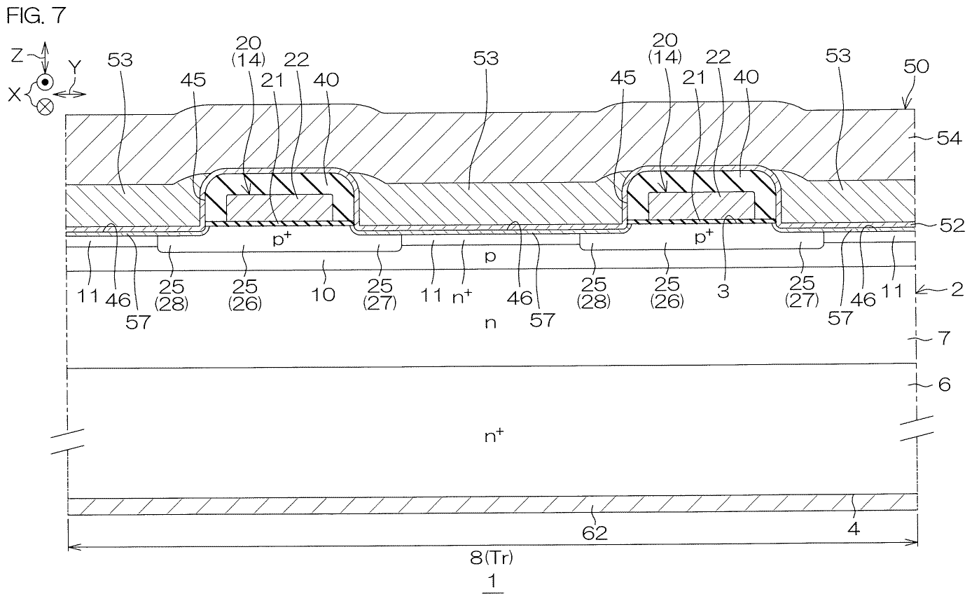

FIG. 1 is a plan view illustrating a semiconductor device 1 according to one embodiment. FIG. 2 is a sectional view taken along line II-II shown in FIG. 1. FIG. 3 is a plan view illustrating a layout example of the first main surface 3. FIG. 4 is an enlarged plan view illustrating one main portion of an active region 8 together with a planar structure 14 according to a first layout example. FIG. 5 is a sectional view taken along line V-V shown in FIG. 4. FIG. 6 is a sectional view taken along line VI-VI shown in FIG. 4. FIG. 7 is a sectional view taken along line VII-VII shown in FIG. 4.

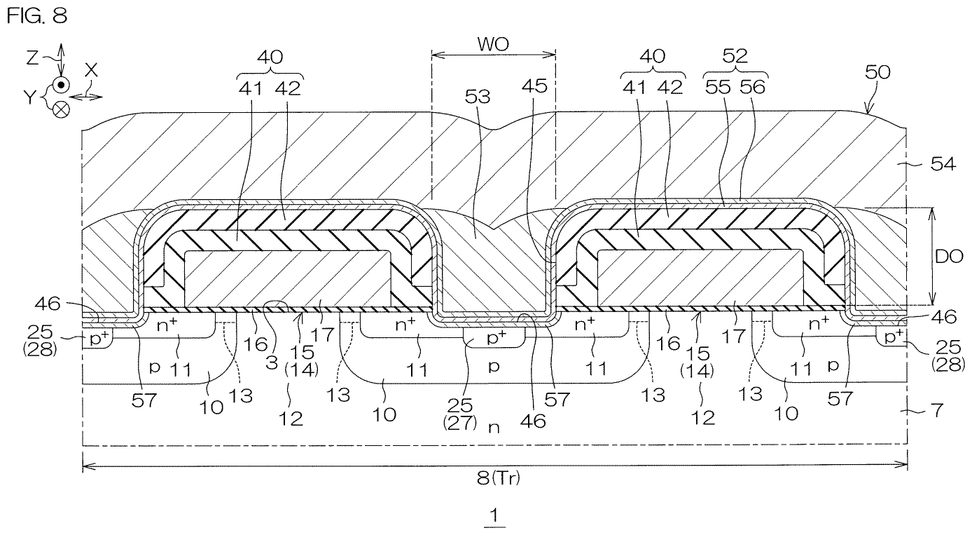

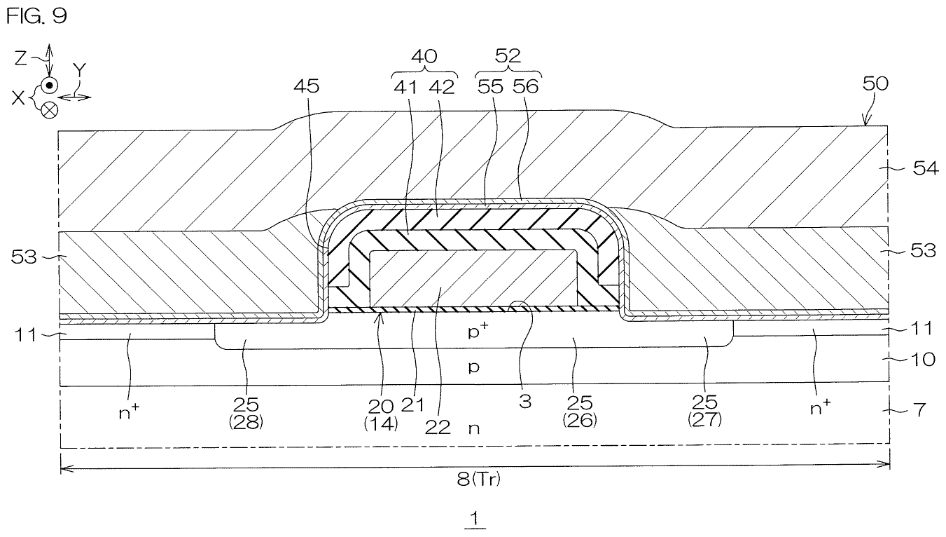

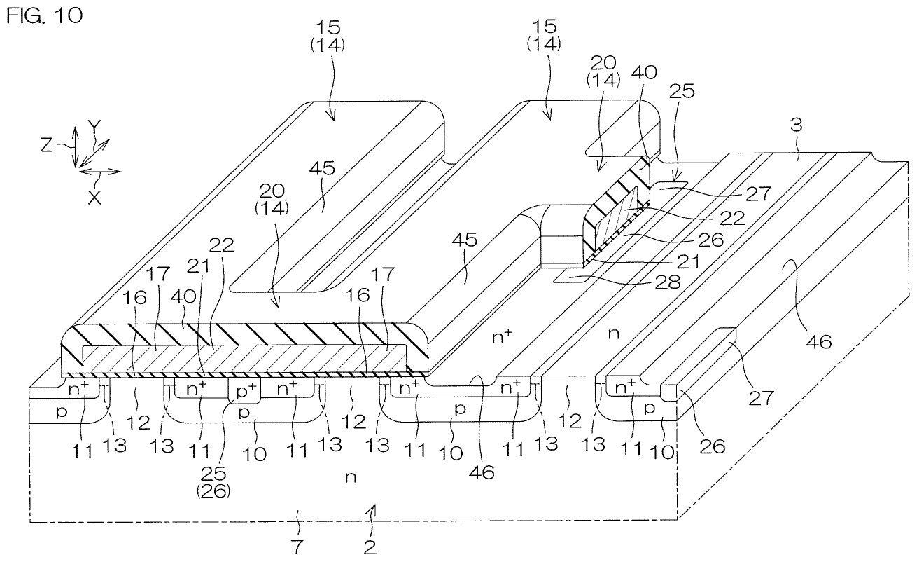

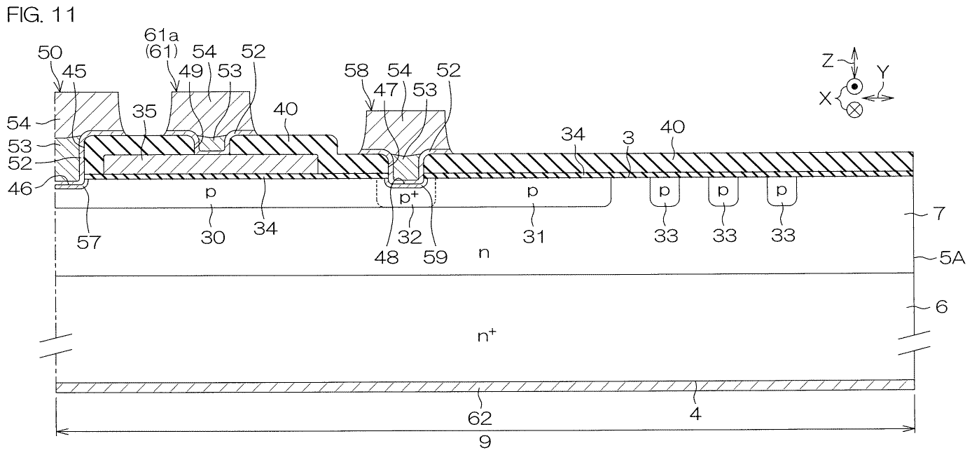

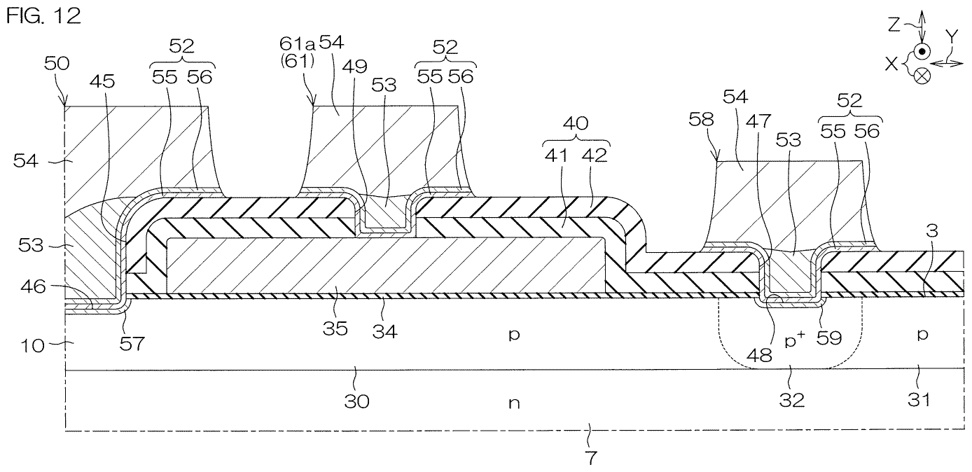

FIG. 8 is an enlarged sectional view illustrating one region shown in FIG. 5. FIG. 9 is an enlarged sectional view illustrating one region shown in FIG. 7. FIG. 10 is a cutaway perspective view illustrating one main portion of the active region. FIG. 11 is a sectional view taken along line XI-XI shown in FIG. 1. FIG. 12 is an enlarged sectional view illustrating one region shown in FIG. 11.

With reference to FIG. 1 to FIG. 12, the semiconductor device 1 is a semiconductor switching device having a transistor structure Tr of an insulated gate type as an example of a device structure. The transistor structure Tr has a vertical type structure of a planar gate type.

The semiconductor device 1 includes a chip 2 that is formed in a hexahedral shape (specifically, a rectangular parallelepiped shape). In this embodiment, the chip 2 includes a monocrystal of a wide bandgap semiconductor. That is, the semiconductor device 1 is a “wide bandgap semiconductor device.” The chip 2 may be referred to as a “semiconductor chip” or as a “wide bandgap semiconductor chip.”

The wide bandgap semiconductor is a semiconductor with a wide band gap exceeding a wide band gap of an Si (silicon). GaN (gallium nitride), SiC (silicon carbide), and C (diamond) are exemplified as the wide bandgap semiconductors. In this embodiment, the chip 2 is an “SiC chip” containing a hexagonal SiC monocrystal as an example of the wide bandgap semiconductor. That is, the semiconductor device 1 is an “SiC semiconductor device.”

The hexagonal SiC monocrystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is described, but the chip 2 may include another polytype.

The chip 2 has the first main surface 3 on one side, a second main surface 4 on the other side, and first to fourth side surfaces 5A to 5D connecting the first main surface 3 and the second main surface 4. The first main surface 3 and the second main surface 4 are each formed in a quadrangular shape as viewed in plan view from a vertical direction Z (hereinafter referred to simply as “plan view”). The vertical direction Z is also a thickness direction of the chip 2.

The first main surface 3 and the second main surface 4 are preferably formed by c-planes of the SiC monocrystal. In this case, preferably, the first main surface 3 is formed by a silicon plane ((0001) plane) of the SiC monocrystal, and the second main surface 4 is formed by a carbon plane ((000-1) plane) of the SiC monocrystal.

The first side surface 5A and the second side surface 5B extend in a first direction X along the first main surface 3 and oppose each other in a second direction Y intersecting the first direction X along the first main surface 3. Specifically, the second direction Y is orthogonal to the first direction X. The third side surface 5C and the fourth side surface 5D extend in the second direction Y and oppose each other in the first direction X.

In this embodiment the first direction X is an m-axis direction ([1-100] direction) of the SiC monocrystal, and the second direction Y is an a-axis direction ([11-20] direction) of the SiC monocrystal. The first direction X may be the a-axis direction of the SiC monocrystal, and the second direction Y may be the m-axis direction of the SiC monocrystal. In the following, a direction extending along the first main surface 3 may also be referred to as a “horizontal direction.” The horizontal direction is also an XY plane (a horizontal plane) formed by the first direction X and the second direction Y and is orthogonal to the vertical direction Z.

The chip 2 (the first main surface 3 and the second main surface 4) has an off angle inclined at a predetermined angle in a predetermined off direction with respect to the c-planes of the SiC monocrystal. That is, a c-axis ((0001) axis) of the SiC monocrystal is inclined by the off angle toward the off direction from a vertical axis. Also, the c-planes of the SiC monocrystal are inclined by the off angle with respect to the horizontal plane.

The off direction is preferably the a-axis direction (that is, the second direction Y) of the SiC monocrystal. The off angle may be more than 0° and not more than 10°. The off angle may have a value falling within at least one of ranges of more than 0° and not more than 1°, not less than 1° and not more than 2.5°, not less than 2.5° and not more than 5°, not less than 5° and not more than 7.5°, and not less than 7.5° and not more than 10°.

The off angle is preferably not more than 5°. The off angle is particularly preferably not less than 2° and not more than 4.5°. The off angle is typically set in a range of 4°±0.1°. This Description does not exclude an embodiment in which the off angle is 0° (that is, an embodiment in which the first main surface 3 is an exact c-plane with respect to the c-plane).

The semiconductor device 1 includes a first semiconductor layer 6 of an n-type that is formed in a surface layer portion of the second main surface 4. A drain potential as a first potential (high potential) is to be applied to the first semiconductor layer 6. The first semiconductor layer 6 may be referred to as a “base region (layer),” a “semiconductor region (layer),” a “drain region (layer),” etc.

The first semiconductor layer 6 extends as a layer along the second main surface 4, and is exposed from the second main surface 4 and the first to fourth side surfaces 5A to 5D. In this embodiment, the first semiconductor layer 6 is constituted of a semiconductor layer of the n-type. Specifically, the first semiconductor layer 6 is constituted of a substrate (an SiC substrate) that contains the SiC monocrystal (semiconductor monocrystal), and forms the second main surface 4 and the first to fourth side surfaces 5A to 5D. The first semiconductor layer 6 (substrate) has the off direction aforementioned and the off angle aforementioned.

The first semiconductor layer 6 may have a thickness of not less than 10 μm and not more than 500 μm. The thickness of the first semiconductor layer 6 may have a value falling within at least one of ranges of not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1 includes a second semiconductor region 7 of the n-type that is formed in a surface layer portion of the first main surface 3. The second semiconductor region 7 may be referred to as a “semiconductor region (layer),” a “drift region (layer),” etc. The second semiconductor region 7 has an n-type impurity concentration lower than an n-type impurity concentration of the first semiconductor layer 6. The second semiconductor region 7 is formed in a region on the first main surface 3 side with respect to the first semiconductor layer 6, and is electrically connected to the first semiconductor layer 6.

The second semiconductor region 7 extends as a layer along the first main surface 3, and is exposed from the first main surface 3 and the first to fourth side surfaces 5A to 5D. In this embodiment, the second semiconductor region 7 is constituted of a semiconductor layer of the n-type that is laminated on the first semiconductor layer 6 (substrate). Specifically, the second semiconductor region 7 is constituted of an epitaxial layer (an SiC epitaxial layer) that contains the SiC monocrystal (semiconductor monocrystal), and forms the first main surface 3 and the first to fourth side surfaces 5A to 5D.

The second semiconductor region 7 (epitaxial layer) has the off direction aforementioned and the off angle aforementioned. The second semiconductor layer 7 preferably has a thickness less than the thickness of the first semiconductor layer 6. As a matter of course, the thickness of the second semiconductor region 7 may be greater than the thickness of the first semiconductor layer.

The thickness of the second semiconductor region 7 may be not less than 5 μm and not more than 15 μm. The thickness of the second semiconductor region 7 may have a value falling within at least one of ranges of not less than 5 μm and not more than 7.5 μm, not less than 7.5 μm and not more than 10 μm, not less than 10 μm and not more than 12.5 μm, and not less than 12.5 μm and not more than 15 μm.

The semiconductor device 1 includes an active region 8 that is set in the chip 2. The active region 8 is a region which includes the device structure (the transistor structure Tr), and in which an output current (drain current) is to be generated. The active region 8 is provided in an inner portion of the chip 2 at an interval from a peripheral edge of the first main surface 3 (the first to fourth side surfaces 5A to 5D).

The active region 8 is set in a polygonal shape (a quadrangular shape in this embodiment) having four sides parallel to the peripheral edge of the chip 2 (the first main surface 3) in plan view. A ratio (an area ratio) of a planar area of the active region 8 with respect to a planar area of the first main surface 3 may be not less than 0.5 and not more than 0.95. The area ratio may be not less than 0.5 and not more than 0.6, not less than 0.6 and not more than 0.7, not less than 0.7 and not more than 0.8, not less than 0.8 and not more than 0.9, and not less than 0.9 and not more than 0.95.

The semiconductor device 1 includes an outer region 9 that is set outside the active region 8 in the chip 2. The outer region 9 is a region that does not include the device structure (the transistor structure Tr). The outer region 9 is provided in a peripheral edge portion of the chip 2. That is, the outer region 9 is provided in a region between the peripheral edge of the chip 2 and the active region 8 in plan view. The outer region 9 extends as a band along the active region 8, and is set in a polygonal annular shape (a quadrangular annular shape in this embodiment) that surrounds the active region 8 in plan view.

The semiconductor device 1 includes a plurality of body regions 10 of the p-type that are formed in the surface layer portion of the first main surface 3 in the active region 8. The body region 10 may be referred to as an “impurity region,” a “channel region,” etc. A source potential as a second potential different from the first potential is to be applied to the body regions 10. The source potential may be a reference potential that serves as a basis for a circuit operation. The reference potential may be ground potential.

The body regions 10 are arranged at intervals in the first direction X, and each extend as a band in the second direction Y. That is, the body regions 10 are arranged in a stripe manner extending in the second direction Y. An extending direction of the body regions 10 matches the off direction of the SiC monocrystal. As a matter of course, the body regions 10 may be arranged at intervals in the second direction Y, and each extend as a band in the first direction X. In this case, an extending direction of the body regions 10 intersects (is perpendicular to) the off direction of the SiC monocrystal.

The body regions 10 are formed at an interval on the first main surface 3 side from a bottom portion of the second semiconductor region 7, and face the first semiconductor layer 6 across a part of the second semiconductor region 7. The body regions 10 are preferably formed at an interval on the first main surface 3 side from a depth position of an intermediate portion of the second semiconductor region 7. The body regions 10 are exposed from the first main surface 3.

In regard to the first direction X, the body region 10 may have a width of not less than 1 μm and not more than 10 μm. The width of the body region 10 may have a value falling within at least one of ranges of not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm. The width of the body region 10 is preferably not less than 2 μm and not more than 5 μm.

The semiconductor device 1 includes a plurality of source regions 11 (impurity regions) of the n-type that are each formed in surface layer portions of the body regions 10. The source potential is to be applied to the source regions 11. The source regions 11 each have an n-type impurity concentration higher than a p-type impurity concentration of the body regions 10, and replace the conductivity type of the corresponding body region 10 from the p-type to the n-type. The n-type impurity concentration of the source regions 11 is higher than the n-type impurity concentration of the second semiconductor region 7.

In this embodiment, the source regions 11 are each formed in one-to-one correspondence with respect to the body regions 10. The source regions 11 are formed at intervals inward from both sides of the corresponding body region 10 in the first direction X, and each extend as a band along the extending direction (the second direction Y) of the corresponding body region 10. As a matter of course, in a case where the extending direction of the body regions 10 is set to the first direction X, the source regions 11 may each extend as a band in the first direction X.

The source region 11 is formed at an interval from a bottom portion of the corresponding body region 10 to the first main surface 3 side, and faces the second semiconductor region 7 across a part of the corresponding body region 10. The source regions 11 are exposed from the first main surface 3.

In regard to the first direction X, the source region 11 may have a width of not less than 1 μm and not more than 10 μm. The width of the source region 11 may have a value falling within at least one of ranges of not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm. The width of the source region 11 is preferably not less than 2 μm and not more than 5 μm.

The semiconductor device 1 includes a plurality of surficial drift regions 12 of the n-type that are each formed in regions demarcated between the body regions 10 in the surface layer portion of the second semiconductor region 7. The surficial drift regions 12 may be referred to as a “JFET region,” etc.

In this embodiment, the surficial drift regions 12 each consist of a portion of the second semiconductor region 7. As a matter of course, the surficial drift regions 12 may have an n-type impurity concentration higher than the n-type impurity concentration of the second semiconductor region 7, or may have an n-type impurity concentration lower than the n-type impurity concentration of the second semiconductor region 7.

The surficial drift regions 12 are arranged at intervals in the first direction X, and each extend as a band in the second direction Y, in accordance with a layout of the body regions 10. Also, the surficial drift regions 12 are formed in a stripe manner extending in the second direction Y. As a matter of course, in a case where an extending direction of the body regions 10 is set to the first direction X, the surficial drift regions 12 may each extend as a band in the first direction X. The surficial drift regions 12 each form a JFET structure of a pnp-type with the body regions 10 located on both sides.

The semiconductor device 1 includes a plurality of channel regions 13 of the p-type that are demarcated in the surface layer portions of the body regions 10. The channel regions 13 are defined in regions between the source regions 11 and the surficial drift regions 12 (the second semiconductor region 7) in the surface layer portions of the body regions 10. The channel regions 13 form current paths that extend in the horizontal direction along the first main surface 3.

The semiconductor device 1 includes a planar structure 14 that is arranged on the first main surface 3 in the active region 8. The planar structure 14 includes a plurality of gate structures 15. The gate structures 15 are each arranged on both sides to the body regions 10 on the first main surface 3.

The gate structures 15 are arranged at intervals in the first direction X, and each extend as a band in the second direction Y. That is, the gate structures 15 are arranged in a stripe manner extending in the second direction Y. Also, an extending direction of the gate structures 15 matches the off direction of the SiC monocrystal. As a matter of course, in a case where an extending direction of the body regions 10 is set to the first direction X, the gate structures 15 may each extend as a band in the first direction X.

The gate structures 15 each cover at least one of the channel regions 13 (peripheral edge portions of the body regions 10). The gate structures 15 are each positioned on at least one of the channel regions 13, and each cover at least one of the peripheral edge portions of the body regions 10, at least one of the source regions 11, and one of the surficial drift regions 12.

In this embodiment, the gate structures 15 each cross one of the surficial drift regions 12 in the first direction X, and extend between the peripheral edge portions of the adjacent two body regions 10. Specifically, the gate structures 15 extend between a peripheral edge portion of the source region 11 within the body region 10 on one side and a peripheral edge portion of the source region 11 within the body region 10 on the other side, and each cover two of the source regions 11, one of the surficial drift region 12 and two of the channel regions 13.

The gate structures 15 each have a laminated structure that includes a gate insulating film 16 and a gate electrode 17. The gate insulating film 16 may be referred to as a “first insulating film,” etc. The gate electrode 17 may be referred to as a “first gate electrode,” etc.

The gate insulating films 16 may include at least one of a silicon oxide film, a silicon nitride film, and a silicon oxynitride film. In this embodiment, the gate insulating films 16 has a single layer structure consisting of a silicon oxide film. The gate insulating films 16 preferably include a silicon oxide film consisting of an oxide of the chip 2.

The gate insulating films 16 are each arranged on both sides to the body regions 10 on the first main surface 3, and each cover the first main surface 3 as a film. The gate insulating films 16 are arranged at intervals in the first direction X, and each extend as a band in the second direction Y along the body regions 10. That is, the gate insulating films 16 are arranged in a stripe manner extending in the second direction Y. Also, an extending direction of the gate insulating films 16 matches the off direction of the SiC monocrystal.

The gate insulating films 16 each cover at least one of the channel regions 13 (the peripheral edge portions of the body regions 10). The gate insulating films 16 are each positioned on at least one of the channel regions 13, and each cover at least one of the peripheral edge portions of the body regions 10, at least one of the source regions 11, and one of the surficial drift regions 12.

In this embodiment, the gate insulating films 16 each cross one of the surficial drift regions 12, and each extend between the peripheral edge portions of the adjacent two body regions 10. Specifically, the gate insulating films 16 each extend between the peripheral edge portion of the source region 11 within the body region 10 on one side and the peripheral edge portion of the source region 11 within the body region 10 on the other side, and each cover two of the source regions 11, one of the surficial drift regions 12, and two of the channel regions 13.

In regard to the first direction X, the gate insulating films 16 are formed at intervals from central portions of the source regions 11 (central portions of the body regions 10) to the surficial drift regions 12 side, and expose the central portions of the source regions 11.

The gate insulating film 16 may have a thickness of not less than 10 nm and not more than 150 nm. The thickness of the gate insulating film 16 may have a value falling within at least one of ranges of not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The gate electrodes 17 are each arranged on both sides to the body regions 10 on the first main surface 3. A gate potential as a control potential is to be applied to the gate electrodes 17. The gate electrodes 17 may include either one or both of conductive poly silicon of the p-type and conductive poly silicon of the n-type.

The gate electrodes 17 are each arranged as a film on the gate insulating films 16. The gate electrodes 17 are arranged at intervals in the first direction X, and each formed as a band extending in the second direction Y along the body regions 10. That is, the gate electrodes 17 are arranged in a stripe manner extending in the second direction Y. Also, an extending direction of the gate electrodes 17 matches the off direction of the SiC monocrystal. In this embodiment, in regard to the first direction X, the gate electrodes 17 are each formed at intervals inward form both end portions of the gate insulating films 16, and each expose both end portions of the corresponding gate insulating films 16.

The gate electrodes 17 each face at least one of the channel regions 13 (the peripheral edge portions of the body regions 10) across the corresponding gate insulating film 16. The gate electrodes 17 each covers at least one of the peripheral edge portions of the body regions 10, at least one of the source regions 11, and one of the surficial drift regions 12 across the corresponding gate insulating film 16 so as to face at least one of the channel regions 13.

In this embodiment, the gate electrodes 17 each cross one of the surficial drift regions 12, and each extend between the peripheral edge portions of the adjacent two body regions 10. Specifically, the gate electrodes 17 each extend between the peripheral edge portion of the source region 11 within the body region 10 on one side and the peripheral edge portion of the source region 11 within the body region 10 on the other side, and each face two of the source regions 11, one of the surficial drift regions 12 and two of the channel regions 13 across the corresponding gate insulating film 16.

When a distance between central portions of the gate electrodes 17 (the gate structures 15) is defined as a first pitch P1, the first pitch P1 may be not less than 1 μm and not more than 6 μm. The first pitch P1 may have a value falling within at least one of ranges of not less than 1 μm and not more than 2 μm, not less than 2 μm and not more than 3 μm, not less than 3 μm and not more than 4 μm, not less than 4 μm and not more than 5 μm, and not less than 5 μm and not more than 6 μm. The first pitch P1 is preferably not less than 2.5 μm and not more than 4.5 μm.

The gate electrode 17 may have a width W1 of not less than 1 μm and not more than 5 μm, in regard to the first direction X. The width W1 of the gate electrode 17 may have a value falling within at least one of ranges of not less than 1 μm and not more than 2 μm, not less than 2 μm and not more than 3 μm, not less than 3 μm and not more than 4 μm, and not less than 4 μm and not more than 5 μm. The width W1 of the gate electrode 17 is preferably not less than 1.5 μm and not more than 2.5 μm.

The gate electrode 17 may have a thickness of not less than 0.1 μm and not more than 2 μm. The thickness of the gate electrode 17 may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The planar structure 14 includes a plurality of gate connection structures 20. The gate connection structures 20 are each formed in regions between the gate structures 15 on the first main surface 3, and are each connected to the adjacent two gate structures 15. That is, the gate connection structures 20 each have one end portion that is connected to the gate structure 15 on one side, and the other end portion that is connected to the gate structure 15 on the other side. The gate connection structures 20 form current paths that electrically connect the adjacent two gate structures 15 in the first direction X.

A number of the gate connection structure 20 arranged in a region between the adjacent two gate structures 15 is arbitrary. The single gate connection structure 20 may each be arranged in regions between the adjacent two gate structures 15. In this embodiment, the gate connection structures 20 are each arranged in regions between the adjacent two gate structures 15.

The gate connection structures 20 each overlap the corresponding body region 10 in the thickness direction. In this embodiment, the gate connection structures 20 each have a portion that covers the corresponding source region 11, and overlap the body region 10 across the corresponding source region 11. The gate connection structures 20 expose the corresponding source region 11 from regions on both sides in regard to the second direction Y.

In regard to the first direction X, the gate connection structures 20 are formed at intervals from the surficial drift regions 12 to the inner side of the corresponding body region 10. Therefore, in regard to the first direction X, the gate connection structures 20 are arranged on the inner side of the corresponding body region 10 with respect to both end portions of the corresponding body region 10, and do not overlap the surficial drift regions 12 in the thickness direction.

The gate connection structures 20 each extend as a band in the first direction X, and are arranged at intervals in the second direction Y in regions between the gate structures 15. As a matter of course, in a case where the extending direction of the gate structures 15 (the body regions 10) is set to the first direction X, the gate structures 15 may each extend as a band in the second direction Y, and are arranged at intervals in the first direction X.

The gate connection structures 20 are each connected to the gate structures 15 in a T-shape manner, and each formed a current path of a T-shape manner together with the gate structures 15. Specifically, in regard to the gate connection structures 20 arranged on both sides to the gate structure 15, the gate connection structures 20 arranged on one side of the first direction X are shifted in the second direction Y with respect to the gate connection structures 20 arranged on the other side of the first direction X. That is, the gate connection structures 20 arranged on one side face regions defined between the gate connection structures 20 arranged on the other side in the first direction X.

The gate connection structures 20 each have a laminated structure that includes a connection insulating film 21 and a connection electrode 22. The connection insulating film 21 may be referred to as a “gate connection insulating film,” a “second insulating film,” etc. The connection electrode 22 may be referred to as a “gate connection electrode,” and a “second gate electrode,” etc.

The connection insulating films 21 may include at least one of a silicon oxide film, a silicon nitride film, and a silicon oxynitride film. The connection insulating films 21 preferably include a same type of insulating material as the insulating material of the gate insulating films 16. In this embodiment, the connection insulating films 21 has a single layer structure consisting of a silicon oxide film. The connection insulating films 21 preferably include a silicon oxide film consisting of an oxide of the chip 2.

The connection insulating films 21 are each formed as a film in regions between the gate insulating films 16 on the first main surface 3, and each connected to the adjacent two gate insulating films 16. That is, the connection insulating films 21 each have one end portion that is connected to the gate insulating film 16 on one side, and the other end portion that is connected to the gate insulating film 16 on the other side. In this embodiment, the connection insulating films 21 are formed integrally with the gate insulating films 16, and form a single insulating film with the gate insulating films 16.

The connection insulating films 21 are each overlap the corresponding body region 10 in the thickness direction. In this embodiment, the connection insulating films 21 each have a portion that covers the corresponding source region 11, and each overlap the corresponding body region 10 across the corresponding source region 11. In regard to the first direction X, the connection insulating films 21 are formed at intervals from the surficial drift regions 12 to the inner side of the corresponding body region 10. Therefore, in regard to the first direction X, the connection insulating films 21 are arranged on the inner side with respect to both end portions of the corresponding body region 10, and do not overlap the surficial drift regions 12 in the thickness direction.

The connection insulating films 21 each extend as a band in the first direction X, and are arranged at intervals in the second direction Y in regions between the gate insulating films 16. The connection insulating films 21 are each connected to the gate insulating films 16 in a T-shape manner. Specifically, in regard to the connection insulating films 21 arranged on both sides to the gate insulating film 16, the connection insulating films 21 arranged on one side of the first direction X are shifted in the second direction Y with respect to the connection insulating films 21 arranged on the other side of the first direction X. That is, the connection insulating films 21 arranged on one side face regions defined between the connection insulating films 21 arranged on the other side in the first direction X.

The connection insulating film 21 preferably has a thickness substantially equal to the thickness of the gate insulating film 16. As a matter of course, the thickness of the connection insulating film 21 may be greater than the thickness of the gate insulating film 16, or may be smaller than the thickness of the gate insulating film 16.

The thickness of the connection insulating film 21 may be not less than 10 nm and not more than 150 nm. The thickness of the connection insulating film 21 may have a value falling within at least one of ranges of not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The connection electrodes 22 transmit the gate potential to the gate electrodes 17. The connection electrodes 22 may include either one or both of conductive poly silicon of the p-type and conductive poly silicon of the n-type. The connection electrodes 22 preferably include a same type of conductive material as the conductive material of the gate electrodes 17.

The connection electrodes 22 are each formed as a film in a region between the gate electrodes 17 on the first main surface 3, and are connected to the adjacent two gate electrodes 17. That is, the connection electrodes 22 each have one end portion that is connected to the gate electrode 17 on one side, and the other end portion that is connected to the gate electrode 17 on the other side. In this embodiment, the connection electrodes 22 are formed integrally with the gate electrodes 17, and form a single electrode with the gate electrodes 17.

The connection electrodes 22 are each formed as a film on the corresponding connection insulating film 21. The connection electrodes 22 each extend as a band in the first direction X, and arranged at intervals in the second direction Y in a region between the gate electrodes 17. In this embodiment, in regard to the second direction Y, the connection electrodes 22 are formed at intervals inward from both end portions of the corresponding connection insulating film 21, and expose both end portions of the corresponding connection insulating film 21.

The connection electrodes 22 each face the corresponding body region 10 across the corresponding connection insulating film 21. In this embodiment, the connection electrodes 22 each have a portion that faces the corresponding source region 11 across the corresponding connection insulating film 21.

In regard to the first direction X, the connection electrodes 22 are formed at intervals from the surficial drift regions 12 to the inner side of the corresponding body region 10. Therefore, in regard to the first direction X, the connection electrodes 22 are arranged on the inner side of the corresponding body region 10 with respect to both end portions of the corresponding body region 10, and do not overlap the surficial drift regions 12 in the thickness direction.

The connection electrodes 22 are each connected to the gate electrodes 17 in a T-shape manner. Specifically, in regard to the connection electrodes 22 arranged on the both sides to the gate electrodes 17, the connection electrodes 22 arranged on one side of the first direction X are shifted in the second direction Y with respect to the connection electrodes 22 arranged on the other side of the first direction X. That is, the connection electrodes 22 arranged on one side face regions defined between the connection electrodes 22 arranged on the other side in the first direction X.

When a distance in the second direction Y between central portions of the connection electrodes 22 (the gate connection structures 20) is set as a second pitch P2, the second pitch P2 is preferably not less than the first pitch P1. The second pitch P2 is preferably greater than the first pitch P1. As a matter of course, the second pitch P2 may be substantially equal to the first pitch P1, or may be less than the first pitch P1.

A pitch ratio P2/P1 of the second pitch P2 with respect to the first pitch P1 may be not less than 0.5 and not more than 20. The pitch ratio P2/P1 may have a value falling within at least one of ranges of not less than 0.5 and not more than 1, not less than 1 and not more than 2.5, not less than 2.5 and not more than 5, not less than 5 and not more than 7.5, not less than 7.5 and not more than 10, not less than 10 and not more than 12.5, not less than 12.5 and not more than 15, not less than 15 and not more than 17.5, not less than, and not less than 17.5 and not more than 20. The pitch ratio P2/P1 is preferably not less than 1 and not more than 10.

The connection electrode 22 preferably has a width W2 in the second direction Y that is not less than the width W1 of the gate electrode 17 in the first direction X. In other words, the width W2 of the connection electrode 22 is preferably equal to or greater than the width W1 of the gate electrode 17. The width W2 of the connection electrode 22 may be greater than the width W1 of the gate electrode 17. The width W2 of the connection electrode 22 may be substantially equal to the width W1 of the gate electrode 17. As a matter of course, This Description does not exclude an embodiment wherein the width W2 of the connection electrode 22 is set to be smaller than the width W1 of the gate electrode 17.

A width ratio W2/W1 of the width W2 of the connection electrode 22 with respect to the width W1 of the gate electrode 17 may be not less than 0.5 and not more than 3. The width ration W2/W1 may have a value falling within at least one of ranges of not less than 0.5 and not more than 1, not less than 1 and not more than 1.5, not less than 1.5 and not more than 2, not less than 2 and not more than 2.5, not less than, and not less than 2.5 and not more than 3. The width ration W2/W1 is preferably not less than 1 and not more than 2.

The width W2 of the connection electrode 22 may be not less than 1 μm and not more than 10 μm. The width W2 of the connection electrode 22 may have a value falling within at least one of ranges of not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm. The width W2 of the connection electrode 22 is preferably not less than 1.5 μm and not more than 5 μm.

The connection electrode 22 preferably has a thickness substantially equal to the thickness of the gate electrode 17. As a matter of course, the thickness of the connection electrode 22 may be greater than the thickness of the gate electrode 17, or may be smaller than the thickness of the gate electrode 17.

The thickness of the connection electrode 22 may be not less than 0.1 μm and not more than 2 μm. The thickness of the connection electrode 22 may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The semiconductor device 1 includes a plurality of contact regions 25 of the p-type that are each formed in the surface layer portions of the body regions 10. The contact regions 25 have a p-type impurity concentration higher than the p-type impurity concentration of the body regions 10.

The contact regions 25 may have the p-type impurity concentration higher than the n-type impurity concentration of the source regions 11, and may replace the conductivity type of the source regions 11 from the n-type to the p-type. As a matter of course, the contact regions 25 may be formed in a region outside the source regions 11 in the surface layer portion of the corresponding body region 10, and increase the p-type impurity concentration of the corresponding body region 10.

In regard to the first direction X, the contact regions 25 each have a width W3 less than a width of the corresponding body region 10, and are each formed in a central portion of the corresponding body region 10 at an interval from the both end portions of the corresponding body region 10. The contact regions 25 are each surrounded by the corresponding source region 11. Specifically, the contact regions 25 are each surrounded over an entire circumference (in four directions) by the corresponding source region 11.

The width W3 of the contact region 25 is smaller than the distance between the adjacent two gate electrodes 17 (the gate structures 15). That is, the width W3 of the contact region 25 is smaller than a length of the connection electrode 22 (the gate connection structure 20) in the first direction X. The width W3 of the contact region 25 is preferably less than the width W1 of the gate electrode 17 in the first direction X. The width W3 of the contact region 25 is preferably less than the width W2 of the connection electrode 22 in the second direction Y.

The width W3 of the contact region 25 may be not less than 0.1 μm and not more than 5 μm. The width W3 of the contact region 25 may have a value falling within at least one of ranges of not less than 0.1 μm and not more than 0.5 μm, not less than 0.5 μm and not more than 1 μm, not less than 1 μm and not more than 2 μm, not less than 2 μm and not more than 3 μm, not less than 3 μm and not more than 4 μm, and not less than 4 μm and not more than 5 μm. The width W3 of the contact region 25 is preferably not less than 0.5 μm and not more than 2 μm.

The contact regions 25 are arranged at intervals in the second direction Y in the surface layer portion of the corresponding body region 10. In this embodiment, the contact regions 25 are arrayed in a line along the second direction Y, and face each other in the second direction Y across a part of the corresponding source region 11. In this embodiment, the contact regions 25 are each formed as a band extending in the second direction Y.

In regard to the second direction Y, the contact regions 25 has a length L greater than the width W1 of the gate electrode 17 (the gate structure 15) in the first direction X. The length L of the contact regions 25 is preferably greater than the width W2 of the connection electrode 22 (the gate connection structure 20) in the second direction Y.

A length ratio L/W2 of the length L of the contact region 25 with respect to the width W2 of the connection electrode 22 (the gate connection structure 20) may be more than 1 and not more than 4. The length ratio L/W2 may have a value falling within at least one of ranges of more than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, not less than 2.75 and not more than 3, not less than 3 and not more than 3.25, not less than 3.25 and not more than 3.5, not less than 3.5 and not more than 3.75, not less than, and not less than 3.75 and not more than 4. The length ratio L/W2 is preferably more than 1 and not more than 2.

The length L of the contact region 25 may be not less than 1 μm and not more than 10 μm. The length L of the contact region 25 may have a value falling within at least one of ranges of not less than 1 μm and not more than 2 μm, not less than 2 μm and not more than 3 μm, not less than 3 μm and not more than 4 μm, not less than 4 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm. The length L of the contact region 25 is preferably not less than 1.5 μm and not more than 5 μm.

The contact regions 25 are each formed at an interval from the bottom portion of the corresponding body region 10 to the first main surface 3 side, and face the second semiconductor region 7 across a part of the corresponding body region 10 in the thickness direction. The contact regions 25 each have a bottom portion located on the bottom portion side of the corresponding body region 10 with respect to the bottom portion of the corresponding source region 11.

That is, the contact regions 25 are formed deeper than the corresponding source region 11, and are electrically connected to the corresponding body region 10 in a lower region with respect to a depth position of the bottom portion of the corresponding source region 11. The contact regions 25 are exposed from the first main surface 3.

In this embodiment, the contact regions 25 are each formed in a region located directly beneath (a region on a lower side with respect to) the gate connection structures 20. In this embodiment, the contact regions 25 are each formed in one-to-one correspondence with respect to the gate connection structures 20, and each face the corresponding gate connection structure 20 in the thickness direction (lamination direction). That is, the contact regions 25 each face the corresponding connection electrode 22 across the corresponding connection insulating film 21.

When a distance in the second direction Y between central portions of the contact regions 25 is set as a third pitch P3, the third pitch P3 is substantially equal to the second pitch P2 of the gate connection structures 20. As a matter of course, the third pitch P3 may be greater than the second pitch P2, or may be smaller than the second pitch P2.

The contact regions 25 each have a covered portion 26 (hidden portion), a first lead-out portion 27 and a second lead-out portion 28. A plurality of the covered portions 26 each consist of a portion that is covered (hidden) by the corresponding gate connection structure 20.

A plurality of the first lead-out portions 27 each consist of a portion that is drawn out from the corresponding covered portion 26 to one side of the second direction Y, and exposed from a region outside the gate connection structures 20. The first lead-out portions 27 face each other in the first direction X across the gate electrodes 17.

A plurality of the second lead-out portions 28 each consist of a portion that is drawn out from the corresponding covered portion 26 to the other side of the second direction Y, and exposed from a region outside the gate connection structures 20. The second lead-out portions 28 face each other in the first direction X across the gate electrodes 17.

The second lead-out portions 28 may face the first lead-out portions 27 in the first direction X across the gate electrodes 17. As a matter of course, the second lead-out portions 28 may face regions between the first lead-out portions 27 and the second lead-out portions 28 in the first direction X across the gate electrodes 17.

In regard to one and the other contact regions 25 arranged adjacent in the second direction Y, the first lead-out portion 27 of the contact region 25 arranged on one side is formed at an interval in the second direction Y from the second lead-out portion 28 of the contact region 25 arranged on the other side, and faces the second lead-out portion 28 of the contact region 25 arranged on the other side in the second direction Y across a part of the corresponding source region 11.

Such a configuration is effective in ensuring a connection area of external electrode with respect to the source region 11. Also, this configuration is effective when the gate electrodes 17 are arranged at a narrow pitch. For example, in a region surrounded by two of the gate electrodes 17 and two of the connection electrodes 22, an occupied area of the contact regions 25 (a total planar area of the first lead-out portion 27 and the second lead-out portion 28) is preferably less than an occupied area (planar area) of the source region 11.

A planar area of the first lead-out portion 27 may be less than a planar area of the covered portion 26. As a matter of course, the planar area of the first lead-out portion 27 may be greater than the planar area of the covered portion 26. The planar area of the second lead-out portion 28 may be less than the planar area of the covered portion 26. As a matter of course, the planar area of the second lead-out portion 28 may be greater than the planar area of the covered portion 26.

The second lead-out portion 28 preferably has a lead-out amount in the second direction Y that is substantially equal to a lead-out amount of the first lead-out portion 27 in the second direction Y. As a matter of course, the lead-out amount of the second lead-out portion 28 may be greater than the lead-out amount of the first lead-out portion 27, or may be smaller than the first lead-out portion 27.

The lead-out amount of the first lead-out portion 27 (the second lead-out portion 28) may be not less than 0.1 μm and not more than 2 μm. The lead-out amount of the first lead-out portion 27 (the second lead-out portion 28) may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

With reference to FIG. 11 and FIG. 12, the semiconductor device 1 includes a well region 30 of the p-type that is formed in the surface layer of the first main surface 3 in the outer region 9. The well region 30 is formed in the surface layer potion of the second semiconductor region 7. The well region 30 has a p-type impurity concentration higher than the n-type impurity concentration of the second semiconductor region 7.

The well region 30 preferably has the p-type impurity concentration substantially equal to the p-type impurity concentration of the body regions 10. As a matter of course, the p-type impurity concentration of the well region 30 may be lower than the p-type impurity concentration of the body regions 10, or higher than the p-type impurity concentration of the body regions 10.

The well region 30 is formed in the surface layer potion of the second semiconductor region 7 at an interval from the peripheral edge of the first main surface 3 (the first to fourth side surfaces 5A to 5D) to the inner side (active region 8 side) of the first main surface 3, and extends as a band along the active region 8. The well region 30 has a portion extending as a band in the first direction X in plan view, and a portion extending as a band in the second direction Y in plan view, and demarcates the body regions 10 (the active region 8) from multiple directions in plan view.

In this embodiment, the well region 30 collectively surrounds the body regions 10 (the active region 8) in plan view, and is demarcated in a polygonal annular shape (in this embodiment, a quadrangular annular shape) having four sides parallel to the peripheral edge of the first main surface 3. That is, the well region 30 forms a boundary portion between the active region 8 and the outer region 9. The well region 30 may have edge portions that each connect a portion extending in the first direction X and a portion extending in the second direction Y in an arc shape (preferably a quarter arc shape) in plan view.

The well region 30 is formed at an interval from the bottom portion of the second semiconductor region 7 to the first main surface 3 side, and faces the first semiconductor layer 6 across a part of the second semiconductor region 7. The well region 30 is preferably formed at an interval from the depth position of the intermediate portion of the second semiconductor region 7 to the first main surface 3 side. The well region 30 is exposed from the first main surface 3.

The well region 30 has an inner edge portion located on the inner side of the first main surface 3 (the active region 8 side), and an outer edge portion located on the peripheral edge side of the first main surface 3. The inner edge portion of the well region 30 is connected to the body regions 10 in the portion extending in the first direction X. That is, the well region 30 is electrically connected to the body regions 10 in the surface layer potion of the second semiconductor region 7, and demarcates the surficial drift regions 12 with the body regions 10.

Thus, the source potential is to be applied to the well region 30 via the body regions 10. The well region 30 forms a pn-junction portion with the second semiconductor region 7, and expands a depletion layer in the second semiconductor region 7 during the application of a reverse bias voltage.

The well region 30 is connected to the body regions 10 at an interval from the source regions 11 in the second direction Y. Therefore, the well region 30 does not have the source region 11 in a surface layer potion. Also, the well region 30 is connected to the body regions 10 at an interval from the contact regions 25 in the second direction Y. Therefore, the well region 30 does not have the contact region 25 in the surface layer potion.

The well region 30 preferably has a width greater than the width of the body region 10. The width of the well region 30 is defined by a width in a direction orthogonal to an extending direction. As a matter of course, the width of the well region 30 may be substantially equal to the width of the body region 10, or may be smaller than the width of the body region 10.

A width ratio of the width of the well region 30 with respect to the width of the body region 10 may be not less than 1 and not more than 50. The width ratio may have a value falling within at least one of ranges of not less than 1 and not more than 5, not less than 5 and not more than 10, not less than 10 and not more than 15, not less than 15 and not more than 20, not less than 20 and not more than 25, not less than 25 and not more than 30, not less than 30 and not more than 35, not less than 35 and not more than 40, not less than 40 and not more than 45, not less than, and not less than 45 and not more than 50.

The well region 30 preferably has a thickness (depth) substantially equal to a thickness (depth) of the body region 10. As a matter of course, the thickness of the well region 30 may be smaller than the thickness of the body region 10, or may be greater than the thickness of the body region 10.

The semiconductor device 1 includes a termination region 31 of the p-type that is formed in the surface layer potion of the first main surface 3 in the outer region 9. The termination region 31 may be referred to as a “termination well region,” a “JTE (Junction Termination Extension) region,” etc. The termination region 31 is formed in the surface layer potion of the second semiconductor region 7 in the outer region 9.

The termination region 31 has a p-type impurity concentration different from the p-type impurity concentration of the body regions 10. The p-type impurity concentration of the termination region 31 may be higher than the p-type impurity concentration of the body regions 10, or may be lower than the p-type impurity concentration of the body regions 10. As a matter of course, the p-type impurity concentration of the termination region 31 may be substantially equal to the p-type impurity concentration of the body regions 10.

The termination region 31 has the p-type impurity concentration different from the p-type impurity concentration of the well region 30. The p-type impurity concentration of the termination region 31 may be higher than the p-type impurity concentration of the well region 30, or may be lower than the p-type impurity concentration of the well region 30. As a matter of course, the p-type impurity concentration of the termination region 31 may be substantially equal to the p-type impurity concentration of the well region 30.

The termination region 31 is formed in a region between the peripheral edge of the first main surface 3 and the well region 30 at an interval inward from the peripheral edge of the first main surface 3. The termination region 31 extends as a band along the well region 30 in plan view. The termination region 31 has a portion that extends as a band in the first direction X in plan view, and a portion that extends as a band in the second direction Y in plan view, and demarcates the active region 8 from multiple directions in plan view.

In this embodiment, the termination region 31 surrounds the well region 30 (the active region 8 and the body regions 10) in plan view, and is demarcated in a polygonal annular shape (in this embodiment, a quadrangular annular shape) having four sides parallel to the peripheral edge of the first main surface 3. The termination region 31 may have edge portions that each connect a portion extending in the first direction X and a portion extending in the second direction Y in an arc shape (preferably a quarter arc shape) in plan view.

The termination region 31 is formed at an interval from the bottom portion of the second semiconductor region 7 to the first main surface 3 side, and faces the first semiconductor layer 6 across a part of the second semiconductor region 7. The termination region 31 is preferably formed at an interval from the depth position of the intermediate portion of the second semiconductor region 7 to the first main surface 3 side. The termination region 31 may have a thickness (depth) substantially equal to the thickness (depth) of the well region 30. The thickness of the termination region 31 may be greater than the thickness of the well region 30, or may be smaller than the thickness of the well region 30.

The termination region 31 has an inner edge portion located on the inner side of the first main surface 3 (the active region 8 side), and an outer edge portion located on the peripheral edge side of the first main surface 3. The inner edge portion of the termination region 31 is connected to the outer edge portion of the well region 30. The termination region 31 is thus electrically connected to the well region 30. Also, the termination region 31 is electrically connected to the body regions 10 via the well region 30.

In this embodiment, the inner edge portion of the termination region 31 is connected to the outer edge portion of the well region 30 over an entire circumference. Where the termination region 31 has the p-type impurity concentration substantially equal to the p-type impurity concentration of the well region 30, the termination region 31 may be regarded as a part of the well region 30. The termination region 31 forms a pn-junction portion with the second semiconductor region 7, and expands a depletion layer to the second semiconductor region 7 during the application of the reverse bias voltage.

The termination region 31 (the inner edge portion) has an overlap region 32 that overlaps the outer edge portion of the well region 30 in the surface layer potion of the second semiconductor region 7. The overlap region 32 is a high concentration region that includes the outer edge portion of the well region 30 and the inner edge portion of the termination region 31. That is, the overlap region 32 includes both of the p-type impurity of the well region 30 and the p-type impurity of the termination region 31, and has a p-type impurity concentration higher than both of the p-type impurity concentration of the well region 30 and the p-type impurity concentration of the termination region 31.

The p-type impurity concentration of the overlap region 32 is higher than the p-type impurity concentration of the body regions 10. The p-type impurity concentration of the overlap region 32 may be lower than the p-type impurity concentration of the contact regions 25. As a matter of course, the p-type impurity concentration of the overlap region 32 may be higher than the p-type impurity concentration of the contact regions 25.

The overlap region 32 extends as a band along the well region 30 in plan view. The overlap region 32 has a portion extending as a band in the first direction X in plan view, and a portion extending as a band in the second direction Y in plan view, and demarcates the active region 8 from multiple directions in plan view. In this embodiment, the overlap region 32 is demarcated in a polygonal annular shape (in this embodiment, a quadrangular annular shape) having four sides parallel to the peripheral edge of the first main surface 3. The overlap region 32 preferably has a width greater than the width of the body region 10. As a matter of course, the width of the overlap region 32 may be not more than the width of the body region 10.

The semiconductor device 1 may have a termination contact region (32) of the p-type that has a relatively high impurity concentration, instead of the overlap region 32. In this case, the termination contact region (32) has a p-type impurity concentration higher than both of the p-type impurity concentration of the well region 30 and the p-type impurity concentration of the termination region 31. The p-type impurity concentration of the termination contact region (32) is higher than the p-type impurity concentration of the body regions 10.

The p-type impurity concentration of the termination contact region (32) may be substantially equal to the p-type impurity concentration of the contact regions 25. As a matter of course, the p-type impurity concentration of the termination contact region (32) may be lower than the p-type impurity concentration of the contact regions 25, or may be higher than the p-type impurity concentration of the contact regions 25.

The termination contact region (32) may be formed in either one or both of a surface layer potion of the well region 30 and a surface layer potion of the termination region 31. This structure is effective in a structure where the termination region 31 has the p-type impurity concentration substantially equal to the p-type impurity concentration of the well region 30, and is formed as a part of (as a lead-out portion of) the well region 30.

The semiconductor device 1 has at least one field region 33 of the p-type that is formed in the surface layer potion of the first main surface 3 in the outer region 9. The field region 33 may be formed in an electrically floating state. The field region 33 may be electrically fixed in the source potential.

A number of the field region 33 is arbitrary. The number of the field region 33 may be not less than 1 and not more than 20. The number of the field region 33 may have a value falling within at least one of ranges of not less than 1 and not more than 5, not less than 5 and not more than 10, not less than 10 and not more than 15, not less than, and not less than 15 and not more than 20. The number of the field region 33 is typically not less than 1 and not more than 8. In this embodiment, the semiconductor device 1 includes three field regions 33.

The field regions 33 are formed in the surface layer potion of the second semiconductor region 7 at intervals from each other. The field regions 33 are formed in a region between the peripheral edge of the first main surface 3 and the body regions 10 (the active region 8) at intervals inward from the peripheral edge of the first main surface 3. Specifically, the field regions 33 are formed in a region between the peripheral edge of the first main surface 3 and the well region 30. More specifically, the field regions 33 are arranged at intervals from the outer edge portion of the termination region 31 to the peripheral edge side of the first main surface 3 in a region between the peripheral edge of the first main surface 3 and the termination region 31.

The field regions 33 are each formed as a band extending along the body regions 10 (the termination region 31) in plan view. The field regions 33 each have a portion that extends as a band in the first direction X, and a portion that extends as a band in the second direction Y.

In this embodiment, the field regions 33 are each formed in a polygonal annular shape (in this embodiment, a quadrangular annular shape) surrounding the body regions 10 (the termination region 31) in plan view. Each of the field regions 33 may have edge portions that each connect a portion extending in the first direction X and a portion extending in the second direction Y in an arc shape (preferably a quarter arc shape) in plan view.

The field regions 33 are formed at an interval from the bottom portion of the second semiconductor region 7 to the first main surface 3 side. The field regions 33 are formed at an interval from the depth position of the intermediate portion of the second semiconductor region 7 to the first main surface 3 side. The field regions 33 each form a pn-junction portion with the second semiconductor region 7, and each expand a depletion layer to the second semiconductor region 7 during the application of the reverse bias voltage.

Widths, depths, intervals, p-type impurity concentrations, etc., of the field regions 33 are arbitrary and can take on various values depending on an electric field to be relaxed. The widths of the field regions 33 may be substantially constant, or may be non-uniform. The widths of the field regions 33 may be gradually increased toward the peripheral edge side of the first main surface 3. The widths of the field regions 33 may be gradually decreased toward the peripheral edge side of the first main surface 3.

The depths of the field regions 33 may be substantially constant, or may be non-uniform. The depths of the field regions 33 may be gradually increased toward the peripheral edge side of the first main surface 3. The depths of the field regions 33 may be gradually decreased toward the peripheral edge side of the first main surface 3. As a matter of course, each of the field regions 33 may have a shallow portion formed relatively shallow and a deep portion formed deeper than the shallow portion. The shallow portion may be formed on an inner side, and the deep portion may be formed on an outer side. The shallow portion may be formed on the outer side, and the deep portion may be formed on the inner side.

The intervals of the field regions 33 may be substantially constant, or may be non-uniform. The intervals of the field regions 33 may be gradually increased toward the peripheral edge side of the first main surface 3. The intervals of the field regions 33 may be gradually decreased toward the peripheral edge side of the first main surface 3.

The p-type impurity concentrations of the field regions 33 may be substantially constant, or may be non-uniform. The p-type impurity concentrations of the field regions 33 may be gradually increased toward the peripheral edge side of the first main surface 3. The p-type impurity concentrations of the field regions 33 may be gradually decreased toward the peripheral edge side of the first main surface 3.

The field regions 33 may have the p-type impurity concentration substantially equal to the p-type impurity concentration of the body regions 10. The p-type impurity concentrations of the field regions 33 may be higher than the p-type impurity concentration of the body regions 10, or may be lower than the p-type impurity concentration of the body regions 10.

The field regions 33 may have the p-type impurity concentration substantially equal to the p-type impurity concentration of the well region 30. The p-type impurity concentrations of the field regions 33 may be higher than the p-type impurity concentration of the well region 30, or may be lower than the p-type impurity concentration of the well region 30.

The field regions 33 may have the p-type impurity concentration substantially equal to the p-type impurity concentration of the termination region 31. The p-type impurity concentrations of the field regions 33 may be higher than the p-type impurity concentration of the termination region 31, or may be lower than the p-type impurity concentration of the termination region 31.

The semiconductor device 1 includes a main surface insulating film 34 that covers the first main surface 3. The main surface insulating film 34 may include at least one of a silicon oxide film, a silicon nitride film, and a silicon oxynitride film. The main surface insulating film 34 preferably includes a same type insulating material as either one or both of the insulating material of the gate insulating film 16 and the insulating material of the connection insulating film 21.

In this embodiment, the main surface insulating film 34 has a single layer structure consisting of a silicon oxide film. The main surface insulating film 34 preferably includes a silicon oxide film consisting of an oxide of the chip 2. The main surface insulating film 34 preferably has a thickness substantially equal to either one or both of the thickness of the gate insulating film 16 and the thickness of the connection insulating film 21.

The main surface insulating film 34 collectively covers the second semiconductor region 7, the well region 30, the termination region 31 and the field regions 33 in the outer region 9. The main surface insulating film 34 has portions that are connected to the gate insulating films 16 on the active region 8 side. In this embodiment, the main surface insulating film 34 has portions that are connected to the connection insulating films 21 on the active region 8 side. In this embodiment, the main surface insulating film 34 is formed integrally with the gate insulating films 16 and the connection insulating films 21, and forms a single insulating film with the gate insulating films 16 and the connection insulating films 21.

The semiconductor device 1 includes a gate wiring 35 that is arranged on the first main surface 3 in the outer region 9. The gate wiring 35 is selectively routed over the first main surface 3, and has a portion that extends in a direction different from the extending direction of the gate electrodes 17. The gate wiring 35 is connected to the gate electrodes 17, and transmits the gate signal to the gate electrodes 17. The gate wiring 35 may be referred to as a “third gate electrode,” etc.

The gate wiring 35 may include either one or both of conductive poly silicon of the p-type and conductive poly silicon of the n-type. The gate wiring 35 preferably includes a same type of conductive material as either one or both of the conductive material of the gate electrode 17 and the conductive material of the connection electrode 22.

The gate wiring 35 is arranged on the main surface insulating film 34 at an interval from the peripheral edge of the first main surface 3 to the inner side of the first main surface 3 (the active region 8 side) in the outer region 9. The gate wiring 35 is arranged at an interval from the innermost field region 33 to the active region 8 side, and exposes all of the field regions 33. In this embodiment, the gate wiring 35 is arranged at an interval from the termination region 31 to the active region 8 side, and is arranged on a portion of the main surface insulating film 34 that covers the well region 30.

That is, the gate wiring 35 faces the well region 30 across the main surface insulating film 34. In this embodiment, the gate wiring 35 is formed narrower than the well region 30 in plan view, and is formed over the well region 30 at intervals from the inner and outer edge portions of the well region 30. The gate wiring 35 is arranged at an interval from the overlap region 32 of the termination region 31 to the active region 8 side. The gate wiring 35 may have a portion that faces the termination region 31 in a laminated direction.

The gate wiring 35 extends as a band along the gate electrodes 17 (the active region 8) in plan view. The gate wiring 35 has a portion that extends as a band in the first direction X in plan view, and a portion that extends as a band in the second direction Y in plan view, and demarcates the body regions 10 (the active region 8) from multiple directions in plan view. In this embodiment, the gate wiring 35 is defined in a polygonal annular shape (in this embodiment, a quadrangular annular shape) having four sides parallel to the peripheral edge of the first main surface 3 in plan view, and surrounds the body regions 10 (the gate structures 15). The gate wiring 35 may be formed in an ended manner or an endless manner.

In this embodiment, the gate wiring 35 extends as a band (in this embodiment, an annular shape) along the well region 30 in plan view, and faces the well region 30 across the main surface insulating film 34 over an entire region in the laminated direction. The gate wiring 35 may have edge portions that each connect a portion extending in the first direction X and a portion extending in the second direction Y in an arc shape (preferably a quarter arc shape) in plan view.

The gate wiring 35 has an inner edge portion on the inner side of the first main surface 3 (the active region 8 side) and an outer edge portion on the peripheral edge side of the first main surface 3. The inner edge portion of the gate wiring 35 is connected to the gate electrodes 17 in the portion extending in the first direction X. The gate wiring 35 thereby transmits the gate potential to the gate electrodes 17.

In this embodiment, the inner edge portion of the gate wiring 35 has portions that are connected to the connection electrodes 22, in the portion extending in the second direction Y. The gate wiring 35 thereby transmits the gate potential to the gate electrodes 17 via the connection electrodes 22. The gate wiring 35 has a thickness substantially equal to either one or both (in this embodiment, both) of the thickness of the gate electrode 17 and the thickness of the connection electrode 22. In this embodiment, the gate wiring 35 is formed integrally with the gate electrodes 17 and the connection electrodes 22, and forms a single electrode with the gate electrodes 17 and the connection electrodes 22.

The gate wiring 35 preferably has a width greater than the width of the gate electrode 17. The width of the gate wiring 35 is a width in a direction orthogonal to the extending direction of the gate wiring 35. As a matter of course, the width of the gate wiring 35 may be smaller than the width of the gate electrode 17. The width of the gate wiring 35 is preferably greater than the width of the connection electrode 22. As a matter of course, the width of the gate wiring 35 may be smaller than the width of the connection electrode 22.

For example, a wiring width ratio of the width of the gate wiring 35 with respect to the width of the gate electrode 17 may be not less than 1 and not more than 50. The wiring width ratio may have a value falling within at least one of ranges of not less than 1 and not more than 5, not less than 5 and not more than 10, not less than 10 and not more than 15, not less than 15 and not more than 20, not less than 20 and not more than 25, not less than 25 and not more than 30, not less than 30 and not more than 35, not less than 35 and not more than 40, not less than 40 and not more than 45, not less than, and not less than 45 and not more than 50.

The semiconductor device 1 includes an interlayer film 40 of an insulation property that covers the first main surface 3. The interlayer film 40 may be referred to as an “interlayer insulating film,” an “intermediate insulating film,” etc. The interlayer film 40 collectively covers the active region 8 and the outer region 9 on the first main surface 3.

The interlayer film 40 covers the gate structures 15 and the gate connection structures 20 in the active region 8. The interlayer film 40 collectively covers the second semiconductor region 7, the well region 30, the termination region 31 and the field regions 33 across the main surface insulating film 34 in the outer region 9.

The interlayer film 40 covers the gate wiring 35 in the outer region 9. The interlayer film 40 is continuous with the first to fourth side surfaces 5A to 5D. The interlayer film 40 may be formed at an interval inward from the first to fourth side surfaces 5A to 5D, and may expose a peripheral edge portion of the first main surface 3 (the second semiconductor region 7).

In this embodiment, the interlayer film 40 has a laminated structure that includes a first interlayer film 41 and a second interlayer film 42 that are laminated in that order from the first main surface 3 side. The first interlayer film 41 has a single layer structure consisting of an undoped silicon oxide film. The first interlayer film 41 may be referred to as an NSG film (Nondoped Silicate Glass film).

The first interlayer film 41 has a thickness greater than the thickness of the gate insulating film 16. In this embodiment, the thickness of the first interlayer film 41 is less than the thickness of the gate electrode 17. The thickness of the first interlayer film 41 may be greater than the thickness of the gate electrode 17. In this embodiment, the thickness of the first interlayer film 41 is less than the thickness of the connection electrode 22. The thickness of the first interlayer film 41 may be greater than the thickness of the connection electrode 22.

The first interlayer film 41 collectively covers the active region 8 and the outer region 9. The first interlayer film 41 collectively covers the gate structures 15 and the gate connection structures 20 in the active region 8.

In regard to the gate structures 15, the first interlayer film 41 covers both of the gate insulating films 16 and the gate electrodes 17 as a film. The first interlayer film 41 has portions that cover the gate insulating films 16 as a film along the horizontal direction, portions that cover side walls of the gate electrodes 17 as a film along the laminated direction, and portions that cover electrode surfaces of the gate electrodes 17 as a film along the horizontal direction.

In regard to the gate connection structures 20, the first interlayer film 41 covers both of the connection insulating films 21 and the connection electrodes 22 as a film. The first interlayer film 41 has portions that cover the connection insulating films 21 as a film along the horizontal direction, portions that cover side walls of the connection electrodes 22 as a film along the laminated direction, and portions that cover electrode surfaces of the connection electrodes 22 as a film along the horizontal direction.

The first interlayer film 41 collectively covers the second semiconductor region 7, the well region 30, the termination region 31 and the field regions 33 across the main surface insulating film 34 in the outer region 9. The first interlayer film 41 covers the gate wiring 35 as a film in the outer region 9. The first interlayer film 41 has a portion that covers the main surface insulating film 34 as a film along the horizontal direction, portions that cover side walls of the gate wiring 35 as a film along the laminated direction, and a portion that covers electrode surface of the gate wiring 35 as a film along the horizontal direction.

The second interlayer film 42 may have a single layer structure consisting of a silicon oxide film containing phosphorus, or may have a laminated structure that includes a silicon oxide film containing phosphorus. The silicon oxide film containing phosphorus may contain boron. The silicon oxide film containing phosphorus may be referred to as a PSG film (Phosphorus Silicon Glass film). The silicon oxide film containing phosphorus and boron may be referred to as a BPSG film (Boron Phosphorus Silicon Glass film).

The second interlayer film 42 may have a single layer structure consisting of the PSG film or the BPSG film laminated on the first interlayer film 41. The second interlayer film 42 may have a laminated structure that includes the PSG film laminated on the first interlayer film 41, and the BPSG film laminated on the PSG film. The second interlayer film 42 may have a laminated structure that includes the BPSG film laminated on the first interlayer film 41, and the PSG film laminated on the BPSG film.

In this embodiment, as one example, the second interlayer film 42 has a single layer structure consisting of the PSG film. The second interlayer film 42 has a thickness greater than the thickness of the gate insulating film 16. The thickness of the second interlayer film 42 may be greater than the thickness of the first interlayer film 41. The thickness of the second interlayer film 42 may be smaller than the thickness of the first interlayer film 41.

The thickness of the second interlayer film 42 may be smaller than the thickness of the gate electrode 17. The thickness of the second interlayer film 42 may be greater than the thickness of the gate electrode 17. The thickness of the second interlayer film 42 may be smaller than the thickness of the connection electrode 22. The thickness of the second interlayer film 42 may be greater than the thickness of the connection electrode 22.

The second interlayer film 42 covers the first interlayer film 41 as a film, and collectively covers the active region 8 and the outer region 9 across the first interlayer film 41. The second interlayer film 42 collectively covers the gate structures 15 and the gate connection structures 20 across the first interlayer film 41 in the active region 8.

In regard to the gate structures 15, the second interlayer film 42 covers both of the gate insulating films 16 and the gate electrodes 17 as a film across the first interlayer film 41. The second interlayer film 42 has portions that cover the gate insulating films 16 across the first interlayer film 41, portions that cover the side walls of the gate electrodes 17 across the first interlayer film 41, and portions that cover the electrode surfaces of the gate electrodes 17 across the first interlayer film 41.

The second interlayer film 42 extends along the side walls of the gate electrodes 17 from regions directly above the gate insulating films 16. As a matter of course, the second interlayer film 42 has portions that extend in the horizontal direction along the gate insulating films 16 in the regions directly above the gate insulating films 16.

In regard to the gate connection structures 20, the second interlayer film 42 covers both of the connection insulating films 21 and the connection electrodes 22 as a film across the first interlayer film 41. The second interlayer film 42 has portions that cover the connection insulating films 21 across the first interlayer film 41, portions that cover the side walls of the connection electrodes 22 across the first interlayer film 41, and portions that cover the electrode surfaces of the connection electrodes 22 across the first interlayer film 41.

The second interlayer film 42 collectively covers the second semiconductor region 7, the well region 30, the termination region 31 and the field regions 33 across the main surface insulating film 34 and the first interlayer film 41 in the outer region 9. The second interlayer film 42 covers the gate wiring 35 across the first interlayer film 41 in the outer region 9. The second interlayer film 42 has a portion that covers the main surface insulating film 34 across the first interlayer film 41, portions that cover the side walls of the gate wiring 35 across the first interlayer film 41, and a portion that cover the electrode surface of the gate wiring 35 across the first interlayer film 41.

The second interlayer film 42 forms an insulating surface that is smoothed by a reflow process and in which an unevenness is reduced. A diffusion of impurities from the second interlayer film 42 with respect to the gate electrodes 17 is suppressed by the first interlayer film 41. This suppresses fluctuations in electrical characteristics (for example, resistance value) of the gate electrodes 17.

A diffusion of impurities of the second interlayer film 42 with respect to the connection electrodes 22 is suppressed by the first interlayer film 41. This suppresses fluctuations in electrical characteristics (for example, the resistance value) of the connection electrodes 22. A diffusion of impurities of the second interlayer film 42 with respect to the gate wiring 35 is suppressed by the first interlayer film 41. This suppresses fluctuations in electrical characteristics (for example, resistance value) of the gate wiring 35.

The semiconductor device 1 includes a plurality of source openings 45 that are formed in the interlayer film 40 in the active region 8. The source openings 45 are formed at intervals from the gate electrodes 17 and the connection electrodes 22 respectively, and arrayed in a line in the second direction Y in regions between the adjacent gate electrodes 17.

Specifically, the source openings 45 are each formed in a region demarcated by the gate electrodes 17 and the connection electrodes 22. The source openings 45 are each demarcated in a quadrangular shape in plan view. In this embodiment, the source openings 45 are each demarcated as a band (rectangular shape) extending in the second direction Y.

In this embodiment, the source openings 45 are formed in a staggered pattern at intervals in the first direction X and the second direction Y in plan view. Specifically, in regard to the source openings 45 arranged on both sides of the gate structure 15, the source openings 45 demarcated on one side of the first direction X are shifted in the second direction Y with respect to the source openings 45 demarcated on the other side of the first direction X.

That is, the source openings 45 demarcated on one side face regions between the source openings 45 demarcated on the other side in the first direction X. In this embodiment, in regard to the first direction X, the source openings 45 face the gate connection structures 20 (the connection electrode 22), one end portion of the source opening 45 on one side of the second direction Y, and the other end portion of the source opening 45 on the other side of the second direction Y.

The source openings 45 penetrate through the gate insulating film 16, the connection insulating film 21 and the interlayer film 40, and each expose the corresponding source region 11 and the corresponding contact regions 25. The source openings 45 each expose the first lead-out portion 27 of the contact region 25 on one side of the second direction Y, and the second lead-out portion 28 of the contact region 25 on the other side of the second direction Y. The source openings 45 each have an opening end that is demarcated in an arc shape by the interlayer film 40 (the second interlayer film 42).

In regard to the first direction X, the source opening 45 may have an opening width WO of not less than 0.1 μm and not more than 3 μm. The opening width WO may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, and not less than 2.75 μm and not more than 3 μm. The opening width WO is preferably not less than 0.75 μm and not more than 2.25 μm.

The source opening 45 may have an opening depth DO of not less than 0.1 μm and not more than 2 μm. The opening depth DO may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The opening depth DO is preferably not less than 0.5 μm and not more than 1.5 μm.

The source opening 45 preferably has an aspect ratio DO/WO of not less than 0.5 and not more than 3. The aspect ratio DO/WO is defined by a ratio of the opening depth DO with respect to the opening width WO. The aspect ratio DO/WO may have a value falling within at least one of ranges of not less than 0.5 and not more than 1, not less than 1 and not more than 1.5, not less than 1.5 and not more than 2, not less than 2 and not more than 2.5, not less than, and not less than 2.5 and not more than 3.

The aspect ratio DO/WO is preferably greater than 1. That is, the source openings 45 are preferably each formed in a vertically long shape in a cross sectional view. This structure contributes a narrow pitch arrangement in regard to the body regions 10 and the gate structures 15.

A layout of the gate connection structures 20 increases a current path in such a narrow pitch arrangement, and it is therefore effective in reducing a resistance value of the entire planar structure 14. Also, a layout of the source regions 11 and the contact regions 25 has appropriate connections to external electrodes in such a narrow pitch arrangement, and it is therefore effective in improving electrical response characteristics.

The aspect ratio DO/WO of the vertically long source opening 45 may have a value falling within at least one of ranges of more than 1 and not less than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, not less than, and not less than 2.75 and not more than 3. The aspect ratio DO/WO is preferably not more than 2.

The semiconductor device 1 includes a plurality of source recesses 46 that are formed in portions of the first main surface 3 that are exposed from the source openings 45. The semiconductor device 1 does not necessarily have to include the source recess 46. Therefore, a configuration without the source recess 46 may be employed.

The source recesses 46 each have a planar shape that matches a planar shape of the corresponding source opening 45, and are recessed toward the second main surface 4 side from the first main surface 3. The source recesses 46 are each formed at an interval from the bottom portion of the corresponding body region 10 to the first main surface 3 side. The source recesses 46 are each formed at an interval from the bottom portion of the corresponding source region 11 and the bottom portion of the corresponding contact regions 25 to the first main surface 3 side.

The source recesses 46 each expose the corresponding source region 11 and the corresponding contact regions 25. The source recesses 46 each expose the first lead-out portion 27 of the contact region 25 on one side of the second direction Y and the second lead-out portion 28 of the contact region 25 on the other side of the second direction Y.

The semiconductor device 1 includes at least one outer opening 47 (in this embodiment, a plurality of outer openings 47) that are formed in the interlayer film 40 in the outer region 9. The outer openings 47 are formed in a portion of the interlayer film 40 that covers the termination region 31. The outer openings 47 penetrate through the main surface insulating film 34 and the interlayer film 40, and expose the termination region 31.

In this embodiment, the outer openings 47 expose the overlap region 32 of the termination region 31. The outer openings 47 may expose the well region 30, instead of or in addition to the termination region 31 (the overlap region 32). The outer openings 47 each have an opening end that is demarcated in an arc shape by the interlayer film 40 (the second interlayer film 42).

The outer openings 47 are formed at intervals along the termination region 31 (the overlap region 32). The outer openings 47 may each be formed in a quadrangular (square) shape, a rectangular shape, a hexagonal shape, a circular shape, etc., in plan view. The outer openings 47 may be formed as a band extending along the termination region 31 (the overlap region 32) in plan view.

The semiconductor device 1 may have a single outer opening 47. The single outer opening 47 may be formed as a band extending along the termination region 31 (the overlap region 32) in plan view. The single outer opening 47 may have a portion extending as a band in the first direction X and a portion extending as a band in the second direction Y in plan view.

The single outer opening 47 may be formed in a polygonal annular shape (for example, a quadrangular annular shape) of an ended manner or an endless manner that has four sides parallel to the peripheral edge of the first main surface 3. The single outer opening 47 may be formed so as to conform to the termination region 31 (the overlap region 32) in plan view, and may have edge portions that each connect a portion extending in the first direction X and a portion extending in the second direction Y in an arc shape (preferably a quarter arc shape) in plan view.

The semiconductor device 1 includes a plurality of outer recesses 48 that are each formed in portions of the first main surface 3 that are exposed from the outer openings 47. The semiconductor device 1 does not necessarily have to include the outer recess 48. Therefore, a configuration without the outer recess 48 may be employed.

The outer recesses 48 each have a planar shape that matches a planar shape of the corresponding outer opening 47, and are recessed toward the second main surface 4 side from the first main surface 3. The outer recesses 48 are formed at an interval from the bottom portion of the termination region 31 (the overlap region 32) to the first main surface 3 side, and expose the termination region 31 (the overlap region 32). In a case where the single outer opening 47 is formed, a single outer recess 48 having a planar shape that matches the planar shape of the single outer opening 47 is formed. The outer recess 48 may have a depth substantially equal to a depth of the source recess 46.

The semiconductor device 1 includes a plurality of gate openings 49 that are formed in the interlayer film 40 in the outer region 9. In this embodiment, the gate openings 49 include one or a plurality of (in this embodiment, a plurality of) gate openings 49 that are formed in a portion of the interlayer film 40 that covers the gate wiring 35, and a plurality of gate openings 49 that are formed in portions of the interlayer film 40 that cover the gate electrodes 17.

The gate openings 49 are formed at intervals along the gate wiring 35 on the outer region 9 side. The gate openings 49 penetrate through the interlayer film 40, and each expose a part of the gate wiring 35.

The gate openings 49 penetrate through the interlayer film 40 on the active region 8 side, and each expose an inner portion (in this embodiment, intermediate portion) of the corresponding gate electrode 17. The gate openings 49 each have an opening end that is demarcated in an arc shape by the interlayer film 40 (the second interlayer film 42).

The gate openings 49 may each be formed in a quadrangular (square) shape, a rectangular shape, a hexagonal shape, a circular shape, etc., in plan view. The semiconductor device 1 may have a single gate opening 49 on the outer region 9 side. The single gate opening 49 may be formed as a band extending along the gate wiring 35. The single gate opening 49 may have a portion that extends as a band in the first direction X in plan view and a portion that extends as a band in the second direction Y in plan view.

The single gate opening 49 may be formed in a polygonal annular shape (for example, a quadrangular annular shape) of an ended manner or an endless manner that has four sides parallel to the peripheral edge of the first main surface 3. The single gate opening 49 may be formed so as to conform to the gate wiring 35 in plan view, and may have edge portions that each connect a portion extending in the first direction X and a portion extending in the second direction Y in an arc shape (preferably a quarter arc shape) in plan view.

The semiconductor device 1 includes a source pad electrode 50 that is arranged on the first main surface 3. The source pad electrode 50 is a terminal electrode to which the source potential is to be applied from outside. The source pad electrode 50 may be referred to as a “source pad,” a “first pad electrode,” a “first main surface electrode,” a “first terminal electrode,” etc.

The source pad electrode 50 is arranged on a portion of the interlayer film 40 that covers the active region 8. The source pad electrode 50 covers the gate electrodes 17 and the connection electrodes 22 across the interlayer film 40, and is electrically isolated from the gate electrodes 17 and the connection electrodes 22 by the interlayer film 40.

The source pad electrode 50 enters into the source openings 45 from on the interlayer film 40, and is electrically connected to the source regions 11 and the contact regions 25 inside the source openings 45. The source pad electrode 50 is electrically connected to the first lead-out portion 27 of the contact region 25 on one side of the second direction Y and the second lead-out portion 28 of the contact region 25 on the other side of the second direction Y inside the source opening 45.

In this embodiment, the source pad electrode 50 includes a notched portion 51 that extends in the first direction X from a middle portion of a periphery on the third side surface 5C side toward the fourth side surface 5D side. The source pad electrode 50 has a first pad portion 50a and a second pad portion 50b that are demarcated in one side and the other side of the second direction Y by the notched portion 51.

The first pad portion 50a is arranged on the first side surface 5A side with respect to a central portion of the first main surface 3 (specifically, the gate openings 49), and formed as a band extending in the first direction X. The second pad portion 50b is arranged on the second side surface 5B side with respect to the central portion of the first main surface 3 (specifically, the gate openings 49), and formed as a band extending in the first direction X. The second pad portion 50b is connected to the first pad portion 50a in a region on the fourth side surface 5D side.

The second pad portion 50b has a planar area substantially equal to a planar area of the first pad portion 50a. As a matter of course, the planar area of the second pad portion 50b may be greater than the plane area of the first pad portion 50a, or may be smaller than the plane area of the first pad portion 50a. Either one or both of one end portion of the first pad portion 50a and one end portion of the second pad portion 50b may be used as a terminal portion for a current monitor.

In this embodiment, the source pad electrode 50 (the first pad portion 50a and the second pad portion 50b) has a laminated structure that includes a lower electrode film 52, a plurality of embedded electrodes 53 and a main electrode film 54 that are formed in that order from the chip 2 side.

In this embodiment, the lower electrode film 52 has a laminated structure that includes a first electrode film 55 and a second electrode film 56. In this embodiment, the first electrode film 55 includes a Ti film, and the second electrode film 56 includes a TiN film. The lower electrode film 52 does not necessarily have to have the laminated structure, and may have a single layer structure consisting of only either the first electrode film 55 (Ti film) and the second electrode film 56 (TiN film).

The first electrode film 55 has a thickness less than the thickness of the interlayer film 40. The thickness of the first electrode film 55 may be not less than 10 nm and not more than 100 nm. The thickness of the first electrode film 55 may have a value falling within at least one of ranges of not less than 10 nm and not more than 25 nm, not less than 25 nm and not more than 50 nm, not less than 50 nm and not more than 75 nm, and not less than 75 nm and not more than 100 nm.

The second electrode film 56 has a thickness less than the thickness of the interlayer film 40. The thickness of the second electrode film 56 is preferably greater than the thickness of the first electrode film 55. The thickness of the second electrode film 56 may be not less than 50 nm and not more than 200 nm. The thickness of the second electrode film 56 may have a value falling within at least one of ranges of not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first electrode film 55 collectively covers a region of the interlayer film 40 in which the source openings 45 are formed as a film, and enters into the source openings 45 from on the interlayer film 40. The first electrode film 55 has a portion that covers the insulating surface of the interlayer film 40 as a film, portions that each cover a wall surface of the source opening 45 as a film, and portions that each cover the first main surface 3 as a film.

In this embodiment, the first electrode film 55 has portions that each cover the source recess 46 as a film in the bottom portion of the source opening 45. The first electrode film 55 may cover the source recess 46 as a film at an interval from a height position of the first main surface 3 toward the bottom portion side of the source recess 46. The first electrode film 55 may have a portion that is positioned on the bottom portion side of the source recess 46 with respect to the height position of the first main surface 3, and a portion that is positioned on the insulating surface side of the interlayer film 40 with respect to the height position of the first main surface 3.

The first electrode film 55 is electrically connected to the source regions 11 and the contact regions 25 inside the source openings 45. The first electrode film 55 is electrically connected to the first lead-out portion 27 of the contact region 25 on one side of the second direction Y and the second lead-out portion 28 of the contact region 25 on the other side of the second direction Y inside the source openings 45.

The second electrode film 56 directly covers the first electrode film 55. The second electrode film 56 collectively covers the region of the interlayer film 40 in which the source openings 45 are formed as a film across the first electrode film 55, and enters into the source openings 45 from on the interlayer film 40. The second electrode film 56 has a portion that covers the insulating surface of the interlayer film 40 as a film across the first electrode film 55, portions that each cover the wall surface of the source opening 45 as a film across the first electrode film 55, and portions that each cover the first main surface 3 as a film across the first electrode film 55.

In this embodiment, the second electrode film 56 has portions that each cover the source recess 46 as a film across the first electrode film 55 on the bottom portion of the source opening 45. Where the first electrode film 55 is positioned on the bottom portion side of the source recess 46 with respect to the height position of the first main surface 3, the second electrode film 56 has a portion that is positioned inside the source recess 46. Where the first electrode film 55 has a portion that is positioned on an upper side with respect to the height position of the first main surface 3, a whole of the second electrode film 56 is to be located on the insulating surface side of the interlayer film 40 with respect to the source recess 46.

The second electrode film 56 is electrically connected to the source regions 11 and the contact regions 25 via the first electrode film 55 inside the source openings 45. The second electrode film 56 is electrically connected to the first lead-out portion 27 of the contact region 25 on one side of the second direction Y and the first lead-out portion 27 of the contact region 25 on the other side of the second direction Y via the first electrode film 55 inside the source openings 45.

The embedded electrodes 53 are each embedded in the source opening 45 across the lower electrode film 52. The embedded electrodes 53 include a conductive material different from conductive material of the lower electrode film 52. The embedded electrodes 53 include at least one type of conductive material among tungsten, molybdenum, tungsten alloy, and molybdenum alloy. In this embodiment, the embedded electrodes 53 contain tungsten.

In this embodiment, the embedded electrodes 53 are each embedded in the source openings 45 in one-to-one correspondence across the lower electrode film 52. The embedded electrodes 53 are electrically connected to the source regions 11 and the contact regions 25 via the lower electrode film 52 inside the source openings 45. The embedded electrodes 53 are electrically connected to the first lead-out portion 27 of the contact region 25 on one side of the second direction Y and the first lead-out portion 27 of the contact region 25 on the other side of the second direction inside the source openings 45 via the lower electrode film 52.

Where the lower electrode film 52 is positioned on the bottom portion side of the source recess 46 with respect to the height position of the first main surface 3, the embedded electrode 53 may have a portion that is located inside the source recess 46. Where the lower electrode film 52 has a portion that is positioned on the insulating surface side of the interlayer film 40 with respect to the height position of the first main surface 3, a whole of the embedded electrodes 53 are to be located on an upper side with respect to the source recess 46.

The embedded electrodes 53 each have an electrode surface that is located on the bottom wall side of the source opening 45 (the bottom portion side of the source recess 46) with respect to the insulating surface of the interlayer film 40, and expose a potion of the lower electrode film 52 that covers the insulating surface of the interlayer film 40.

The electrode surfaces of the embedded electrodes 53 are preferably located on the insulating surface side of the interlayer film 40 with respect to height positions of the electrode surfaces of the gate electrodes 17 and the electrode surfaces of the connection electrodes 22. As a matter of course, the electrode surfaces of the embedded electrodes 53 may be located on the bottom wall side of the source openings 45 with respect to the height positions of the electrode surfaces of the gate electrodes 17 and the electrode surfaces of the connection electrodes 22.

The embedded electrodes 53 exhibit effectiveness in enhancing an embeddability to the source openings 45 when the source openings 45 are formed in a vertically elongated shape with the relatively high aspect ratio DO/WO (>1). That is, the embedded electrodes 53 are effective in a structure where the body regions 10 and the gate structures 15 are arranged at a narrow pitch.

The main electrode film 54 includes a conductive material different from the conductive material of the lower electrode film 52 (the first electrode film 55 and the second electrode film 56). The main electrode film 54 may include at least one of an Al film, an Al alloy film, a Cu film, and a Cu alloy film. The Al alloy film may include at least one of an AlSi alloy film, an AlCu alloy film, and an AlSiCu alloy film. The main electrode film 54 has a thickness greater than the thickness (total thickness) of the lower electrode film 52. The thickness of the main electrode film 54 is preferably greater than the thickness of the interlayer film 40.

The thickness of the main electrode film 54 may be not less than 0.5 μm and not more than 5 μm. The thickness of the main electrode film 54 may have a value falling within at least one of ranges of not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The main electrode film 54 directly covers the lower electrode film 52 (the second electrode film 56) and the embedded electrodes 53. The main electrode film 54 has a portion that covers the insulating surface of the interlayer film 40 across the lower electrode film 52, and portions that cover the source openings 45 across the embedded electrodes 53. The main electrode film 54 is electrically connected to the source regions 11 and the contact regions 25 via the lower electrode film 52 and the embedded electrodes 53.

The semiconductor device 1 includes a plurality of first source silicides 57 that are formed in surface layer portions in regions of the first main surface 3 that are exposed from the source openings 45. The first source silicides 57 are formed in the wall surfaces (side walls and bottom walls) of the source recesses 46 as a film, and are mechanically and electrically connected to the corresponding source region 11 and the corresponding contact regions 25.

The first source silicide 57 may include at least one of Ti silicide, Ni silicide, Co silicide, Mo silicide, and W silicide. The first source silicide 57 preferably consists of Ti silicide, Ni silicide, or Co silicide.

The semiconductor device 1 does not necessarily have to include the first source silicide 57. In this case, the lower electrode film 52 is to be mechanically and electrically connected to the source regions 11 and the contact regions 25 inside the source openings 45 (the source recesses 46).

The semiconductor device 1 includes a source finger electrode 58 that is selectively routed around on a portion of the interlayer film 40 that covers the outer region 9. The source finger electrode 58 may be referred to as a “source finger,” a “first finger electrode,” etc.

In this embodiment, the source finger electrode 58 is arranged around the source pad electrode 50, and is connected to an end portion of the source pad electrode 50 (the first pad portion 50a and the second pad portion 50b) on the fourth side surface 5D side. The source finger electrode 58 has a wiring width smaller than an electrode width of the source pad electrode 50, and extends as a band along a periphery of the source pad electrode 50.

In this embodiment, the source finger electrode 58 is formed in a polygonal annular shape (in this embodiment, a quadrangular annular shape) having four sides parallel to the peripheral edge of the first main surface 3 in plan view, and surrounds the source pad electrode 50 in plan view. The source finger electrode 58 may have edge portions that each connect a portion extending in the first direction X and a portion extending in the second direction Y in an arc shape (preferably a quarter arc shape) in plan view. The source finger electrode 58 may be formed in an ended manner or an endless manner.

The source finger electrode 58 is formed at an interval from the peripheral edge of the first main surface 3 to the inner side of the first main surface 3 (the active region 8 side). The source finger electrode 58 is formed at an interval inward from the innermost field region 33. That is, the source finger electrode 58 does not face the field regions 33 across the interlayer film 40. The source finger electrode 58 is formed at an interval inward from the outer edge portion of the termination region 31, and faces the termination region 31 across the interlayer film 40.

The source finger electrode 58 enters into the outer openings 47 from on the interlayer film 40, and is electrically connected to the termination region 31 (the overlap region 32) inside the outer openings 47. In this embodiment, the source finger electrode 58 covers the termination region 31 (the overlap region 32) over an entire circumference.

The source finger electrode 58 has a laminated structure that includes the lower electrode film 52, the embedded electrodes 53 and the main electrode film 54 that are formed in that order from the chip 2 side, as with the case of the source pad electrode 50. The lower electrode film 52 has the laminated structure that includes the first electrode film 55 and the second electrode film 56.

The first electrode film 55 collectively covers a region of the interlayer film 40 in which the outer openings 47 are formed as a film, and enters into the outer openings 47 from on the interlayer film 40. The first electrode film 55 has a portion that covers the insulating surface of the interlayer film 40 as a film, portions that each cover the wall surface of the outer opening 47 as a film, and portions that each cover the first main surface 3 inside the outer openings 47 as a film.

In this embodiment, the first electrode film 55 has portions that each cover the outer recess 48 as a film in the bottom portion of the outer opening 47. The first electrode film 55 may cover the outer recess 48 as a film at an interval from the height position of the first main surface 3 to the bottom wall side of the outer recess 48.

The first electrode film 55 may have a portion that is positioned on the bottom wall side of the outer recess 48 with respect to the height position of the first main surface 3, and a portion that is positioned on the insulating surface side of the interlayer film 40 with respect to the height position of the first main surface 3. The first electrode film 55 is mechanically and electrically connected to the termination region 31 (the overlap region 32) inside the outer openings 47.

The second electrode film 56 directly covers the first electrode film 55. The second electrode film 56 collectively covers the region of the interlayer film 40 in which the outer openings 47 are formed as a film across the first electrode film 55, and enters into the outer openings 47 from on the interlayer film 40.

The second electrode film 56 has a portion that covers the insulating surface of the interlayer film 40 as a film across the first electrode film 55, portions that each cover the wall surface of the outer opening 47 as a film across the first electrode film 55, and portions that each cover the first main surface 3 as a film across the first electrode film 55. In this embodiment, the second electrode film 56 has portions that each cover the outer recess 48 across the first electrode film 55 as a film in the bottom wall of the outer opening 47.

Where the first electrode film 55 is located on the bottom wall side of the outer recess 48 with respect to the height position of the first main surface 3, the second electrode film 56 has a portion that is positioned inside the outer recess 48. Where the first electrode film 55 has a portion that is located on the upper side with respect to the height position of the first main surface 3, a whole of the second electrode film 56 is to be located on the insulating surface side of the interlayer film 40 with respect to the outer recess 48. The second electrode film 56 is electrically connected to the termination region 31 (the overlap region 32) via the first electrode film 55 inside the outer openings 47.

The embedded electrodes 53 are embedded in the outer openings 47 across the lower electrode film 52. The embedded electrodes 53 are electrically connected to the termination region 31 (the overlap region 32) via the lower electrode film 52 inside the outer openings 47.

Where the lower electrode film 52 is positioned on the bottom wall side of the outer recess 48 with respect to the height position of the first main surface 3, the embedded electrode 53 may have a portion that is located inside the outer recess 48. Where the lower electrode film 52 has a portion that is positioned on the insulating surface side of the interlayer film 40 with respect to the height position of the first main surface 3, a whole of the embedded electrode 53 is to be positioned on an upper side with respect to the outer recess 48.

The embedded electrodes 53 each have an electrode surface that is positioned on the bottom wall side of the outer opening 47 (the bottom portion side of the outer recess 48) with respect to the insulating surface of the interlayer film 40, and each expose the portion of the insulating surface of the interlayer film 40 that covers the lower electrode film 52.

The electrode surfaces of the embedded electrodes 53 are preferably positioned on the insulating surface side of the interlayer film 40 with respect to the height positions of the electrode surfaces of the gate electrodes 17 and the electrode surfaces of the connection electrodes 22. As a matter of course, the electrode surfaces of the embedded electrodes 53 are positioned on the bottom wall side of the outer openings 47 with respect to the height positions of the electrode surfaces of the gate electrodes 17 and the electrode surfaces of the connection electrodes 22.

The main electrode film 54 directly covers the lower electrode film 52 (the second electrode film 56) and the embedded electrodes 53. The main electrode film 54 has a portion that covers the insulating surface of the interlayer film 40 across the lower electrode film 52, and portions that cover the outer openings 47 across the embedded electrodes 53. The main electrode film 54 is electrically connected to the termination region 31 (the overlap region 32) via the lower electrode film 52 and the embedded electrodes 53.

The semiconductor device 1 includes a plurality of second source silicides 59 that are formed in surface layer portions in regions of the first main surface 3 that are exposed from the outer openings 47. The second source silicides 59 are each formed as a film along the wall surfaces (side walls and bottom walls) of the outer recesses 48, and mechanically and electrically connected to the termination region 31 (the overlap region 32).

The second source silicide 59 may include at least one of Ti silicide, Ni silicide, Co silicide, Mo silicide, and W silicide. The second source silicide 59 preferably consists of Ti silicide, Ni silicide, or Co silicide. The second source silicide 59 preferably includes a same type of silicide as the silicide of the first source silicides 57.

The semiconductor device 1 does not necessarily have to include the second source silicide 59. In this case, the lower electrode film 52 is to be mechanically and electrically connected to the termination region 31 (the overlap region 32) inside the outer openings 47 (the outer recesses 48).

The semiconductor device 1 includes a gate pad electrode 60 that is formed on the first main surface 3. The gate pad electrode 60 may be referred to as a “second pad electrode,” a “second main surface electrode,” a “second terminal electrode,” etc. The gate pad electrode 60 is a terminal electrode to which the gate potential is to be applied from the outside. Although not shown in the drawings, the gate pad electrode 60 has the lower electrode film 52 that covers the interlayer film 40 as a film, and the main electrode film 54 that covers the lower electrode film 52 as a film, as with the case of the source pad electrode 50.

The gate pad electrode 60 is arranged on a portion of the interlayer film 40 that covers the active region 8 at an interval from the source pad electrode 50. In this embodiment, the gate pad electrode 60 is arranged in a region between the one end portion of the first pad portion 50a and the one end portion of the second pad portion 50b, and faces the first pad portion 50a and the second pad portion 50b in the second direction Y.

The gate pad electrode 60 is formed in a polygonal shape (a quadrangular shape in this embodiment) having four sides parallel to the peripheral edge of the chip 2 in plan view. The gate pad electrode 60 has a planar area smaller than the planar area of the source pad electrode 50. The planar area of the gate pad electrode 60 is smaller than both of the planar area of the first pad portion 50a and the planar area of the second pad portion 50b.

The gate pad electrode 60 faces the gate electrodes 17 and the connection electrodes 22 across the interlayer film 40. Specifically, the gate pad electrode 60 is formed at intervals inward from both end portions of the gate electrodes 17, and faces the inner portions of the gate electrodes 17 across the interlayer film 40. In this embodiment, the gate pad electrode 60 does not have a direct electrical connection portion with respect to the gate electrodes 17 and the connection electrodes 22.

As a matter of course, the gate pad electrode 60 is electrically connected to the gate electrodes 17 via the gate openings 49 (the embedded electrodes 53). As a matter of course, the portions of the gate electrodes 17 that are located directly beneath the gate pad electrode 60 and the portions of the connection electrodes 22 that are located directly beneath the gate pad electrode 60 may be removed. In this case, the gate pad electrode 60 may face the body region 10 across the main surface insulating film 34 and the interlayer film 40.

The semiconductor device 1 includes a plurality of gate finger electrodes 61 that are led out from the gate pad electrode 60 onto the first main surface 3. The gate finger electrodes 61 may be referred to as a “gate finger,” a “second finger electrode,” etc. The gate finger electrodes 61 transmits the gate potential applied to the gate pad electrode 60 to the gate electrodes 17 and the connection electrodes 22.

The gate finger electrodes 61 include a first gate finger electrode 61a, a second gate finger electrode 61b and a third gate finger electrode 61c. The first gate finger electrode 61a is led out from the gate pad electrode 60 to the first side surface 5A side, and extends as an ended band along the first side surface 5A, the third side surface 5C, and the fourth side surface 5D. The first gate finger electrode 61a has a portion that extends as a band in the first direction X, and a portion that extends as a band in the second direction Y.

The first gate finger electrode 61a enters into the gate openings 49 from on the interlayer film 40, and is electrically connected to the gate wiring 35 inside the gate openings 49. The gate potential applied to the gate pad electrode 60 is thereby transmitted to the gate electrodes 17 and the connection electrodes 22 via the first gate finger electrode 61a.

The second gate finger electrode 61b is led out from the gate pad electrode 60 to the second side surface 5B side, and extends as an ended band along the second side surface 5B, the third side surface 5C, and the fourth side surface 5D. The second gate finger electrode 61b has a portion that extends as a band in the first direction X, and a portion that extends as a band in the second direction Y.

The second gate finger electrode 61b enters into the gate openings 49 from on the interlayer film 40, and is electrically connected to the gate wiring 35 inside the gate openings 49. The gate potential applied to the gate pad electrode 60 is thereby transmitted to the gate electrodes 17 and the connection electrodes 22 via the second gate finger electrode 61b.

The third gate finger electrode 61c is led out as a band extending along the first direction X from the gate pad electrode 60 toward the inner portion of the active region 8. Specifically, the third gate finger electrode 61c is arranged in the notched portion 51 at intervals from the first pad portion 50a and the second pad portion 50b, and extends as a band in the first direction X along the notched portion 51.

The third gate finger electrode 61c enters into the gate openings 49 from on the interlayer film 40, and is electrically connected to the gate electrodes 17 inside the gate openings 49. The gate potential applied to the gate pad electrode 60 is thereby transmitted to the gate electrodes 17 and the connection electrodes 22 via the third gate finger electrode 61c.

The gate finger electrodes 61 have a laminated structure that includes the lower electrode film 52, the embedded electrodes 53 and the main electrode film 54 that are laminated in that order from the chip 2 side, as with the case of the source pad electrode 50. The lower electrode film 52 has a laminated structure that includes the first electrode film 55 and the second electrode film 56.

The first electrode film 55 collectively covers a region of the interlayer film 40 in which the gate openings 49 are formed as a film, and enters into the gate openings 49 from on the interlayer film 40. The first electrode film 55 has a portion that covers the insulating surface of the interlayer film 40 as a film, portions that each cover a wall surface of the gate opening 49 as a film, and portions that each cover the gate electrode 17 or the gate wiring 35 as a film. The first electrode film 55 is electrically connected to the gate electrodes 17 and the gate wiring 35 inside the gate openings 49.

The second electrode film 56 directly covers the first electrode film 55. The second electrode film 56 collectively covers the region of the interlayer film 40 in which the gate openings 49 are formed as a film across the first electrode film 55, and enters into the gate openings 49 from on the interlayer film 40.

The second electrode film 56 has a portion that covers the insulating surface of the interlayer film 40 as a film across the first electrode film 55, portions that each cover the wall surface of the gate opening 49 as a film across the first electrode film 55, and portions that each cover the gate electrode 17 or the gate wiring 35 as a film across the first electrode film 55. The second electrode film 56 is electrically connected to the gate electrodes 17 and the gate wiring 35 via the first electrode film 55 inside the gate openings 49.

The embedded electrodes 53 are embedded in the gate openings 49 across the lower electrode film 52. The embedded electrodes 53 are electrically connected to the gate electrodes 17 or the gate wiring 35 via the lower electrode film 52 inside the gate openings 49. The embedded electrodes 53 each have an electrode surface that is positioned on a bottom wall side of the gate opening 49 with respect to the insulating surface of the interlayer film 40, and expose the portion of the lower electrode film 52 that covers the insulating surface of the interlayer film 40.

The main electrode film 54 directly covers the lower electrode film 52 (the second electrode film 56) and the embedded electrodes 53. The main electrode film 54 has a portion that covers the insulating surface of the interlayer film 40 across the lower electrode film 52, and portions that cover the gate openings 49 across the embedded electrodes 53. The main electrode film 54 is electrically connected to the gate electrodes 17 and the gate wiring 35 via the lower electrode film 52 and the embedded electrodes 53.

The semiconductor device 1 includes a drain electrode 62 that covers the second main surface 4. The drain electrode 62 is a terminal electrode to which the drain potential is to be applied from the outside. The drain electrode 62 may be referred to as a “third pad electrode,” a “third main surface electrode,” a “third terminal electrode,” etc.

The drain electrode 62 is electrically connected to the first semiconductor layer 6. The drain electrode 62 may cover a whole region of the second main surface 4 so as to be continuous to the peripheral edge of the second main surface 4 (the first to fourth side surfaces 5A to 5D). The drain electrode 62 may partially cover the second main surface 4 so as to expose a peripheral edge portion of the second main surface 4.

A breakdown voltage to be applied between the source pad electrode 50 and the drain pad electrode 62 (that is, between the first main surface 3 and the second main surface 4) may be not less than 500 V and not more than 3000 V. The breakdown voltage may have a value falling within at least one of ranges of not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, not less than 2500 V and not more than 2750 V, and not less than 2750 V and not more than 3000 V.

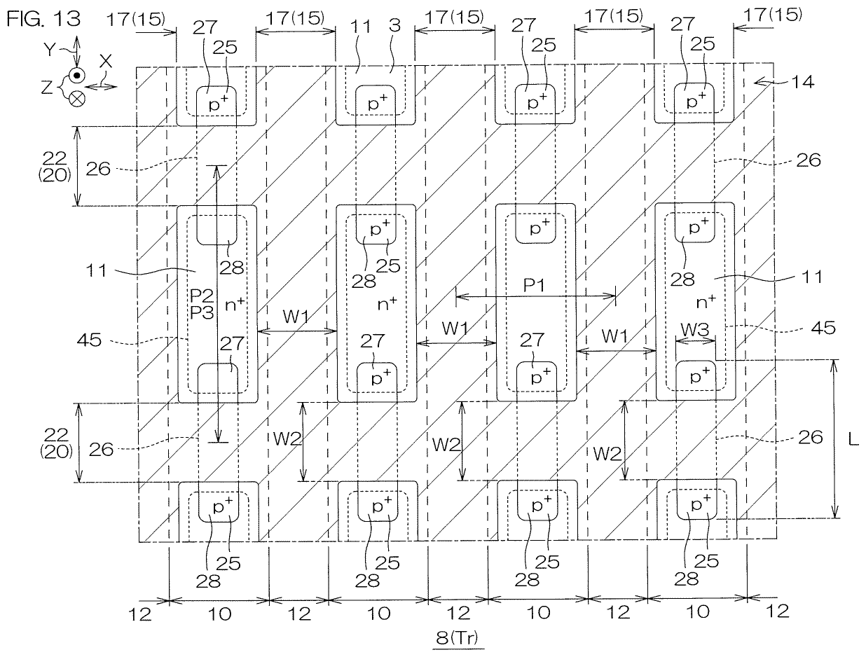

Hereinafter, a layout example of the planar structure 14 shall be described. FIG. 13 is an enlarged plan view illustrating one main portion of the active region 8 together with the planar structure 14 according to a second layout example. In the planar structure 14 according to the first layout example, the gate connection structures 20 are each connected to the gate structures 15 in the T-shape manner.

In contrast, in the planar structure 14 according to the second layout example, the gate connection structures 20 are each connected to the gate structures 15 in a cross-shape manner, and each form a current path of a cross-shape manner together with the gate structures 15. Specifically, in regard to the gate connection structures 20 that are arranged on both sides of the gate structures 15, the gate connection structures 20 arranged on one side of the first direction X each oppose the gate connection structures 20 arranged on the other side of the first direction X in a one-to-one correspondence in the first direction X.

That is, the connection insulating films 21 are each connected to the gate insulating films 16 in the cross-shape manner in regions between the gate insulating films 16. Specifically, in regard to the connection insulating films 21 that are arranged on both sides of the gate insulating films 16, the connection insulating films 21 arranged on one side of the first direction X each oppose the connection insulating films 21 arranged on the other side of the first direction X in a one-to-one correspondence in the first direction X.

Also, the connection electrodes 22 are each connected to the gate electrodes 17 in the cross-shape manner in regions between the gate electrodes 17. Specifically, in regard to the connection electrodes 22 that are arranged on both sides of the gate electrodes 17, the connection electrodes 22 arranged on one side of the first direction X each oppose the connection electrodes 22 on the other side of the first direction X in a one-to-one correspondence in the first direction X.

In this embodiment, the source openings 45 are formed in a matrix manner at intervals in the first direction X and the second direction Y from each other in plan view. Specifically, in regard to the source openings 45 that are arranged on both sides of the gate electrodes 17, the source openings 45 arranged on one side of the first direction X each oppose the source openings 45 arranged on the other side of the first direction X in a one-to-one correspondence in the first direction X.

As a matter of course, the source openings 45 may oppose either one or both of the one end portion of the gate connection structures 20 (the connection electrode 22) and the other end portion of the gate connection structures 20 (the connection electrode 22) in the first direction X. The source openings 45 penetrate through the gate insulating film 16, the connection insulating film 21 and the interlayer film 40, and each expose the corresponding source region 11 and the corresponding contact regions 25, as with the case of the first layout example.

As a matter of course, the semiconductor device 1 may include one or a plurality of gate connection structures 20 that is/are connected to the gate structure 15 in the T-shape manner(see FIG. 4), and one or a plurality of gate connection structures 20 that is/are connected to the gate structure 15 in the cross-shape manner(see FIG. 13).

As described above, the semiconductor device 1 includes the chip 2, the body region 10, the gate electrodes 17 and the connection electrode 22. The chip 2 has the first main surface 3. The body region 10 is formed in the surface layer potion of the first main surface 3. The gate electrodes 17 are formed on both sides of the body region 10 on the first main surface 3. The connection electrode 22 is formed in the region between the gate electrodes 17 on the first main surface 3 so as to overlap the body region 10 in the thickness direction, and is connected to the gate electrodes 17.

According to this structure, the semiconductor device 1 which has a novel structure can be provided. For example, according to the semiconductor device 1, with the connection electrode 22, the current path which connects the gate electrodes 17 is formed. Accordingly, the current path is expanded, and thereby a resistance value of an electrode including the gate electrodes 17 and the connection electrode 22 can be reduced. As a result, switching response characteristics of the semiconductor device 1 can be improved.

The chip 2 may include an SiC. According to this structure, the semiconductor device 1 as an SiC semiconductor device which has a novel structure can be provided. According to the SiC semiconductor device, a withstand voltage can be further enhanced with the physical properties of the SiC. In particular, since the SiC semiconductor device is used in a high-voltage and large-current environment, the reduction in the resistance value (improvement of switching response characteristics) achieved by the connection electrode 22 is also effective in reducing power consumption.

The body region 10 may extend as a band in the one direction (the second direction Y) in plan view. The gate electrodes 17 may each extend as a band in the one direction in plan view. The connection electrode 22 may extend as a band in the crossing direction (the first direction X) intersecting the one direction in plan view. According to this structure, it is possible to achieve a narrow pitch arrangement of the gate electrodes 17. This improves a current handling capacity per unit area. This configuration is also effective in reducing an on-resistance.

The connection electrode 22 may have the width equal to or greater than the width of the gate electrode 17. According to this structure, a current confinement by the connection electrode 22 is properly suppressed in the region between the gate electrodes 17. This allows the resistance value to be appropriately reduced by the connection electrode 22.

The width of the connection electrode 22 may be not more than three times the width of the gate electrode 17. According to this structure, an increase in a hidden area of the body region 10 covered by the connection electrode 22 is suppressed, and a decrease in a channel area due to the connection electrode 22 is suppressed. This achieves the effect of reducing the resistance value with the connection electrode 22 and suppresses an increase in the on-resistance.

The connection electrodes 22 may be formed in the region between the gate electrodes 17 on the first main surface 3 so as to overlap the body region 10 in the thickness direction, and may each be connected to the gate electrodes 17. According to this structure, the current path can be expanded by the connection electrodes 22 connected to the gate electrodes 17. This allows the resistance value of the electrode including the gate electrodes 17 and the connection electrode 22 to be reduced.

The semiconductor device 1 may include the source region 11 (impurity region) and the contact region 25. The source region 11 may have the conductivity type different from the conductivity type of the body region 10, and may be formed in the surface layer portion of the body region 10. The contact region 25 may have the same conductivity type as the conductivity type of the body region 10, may have the impurity concentration higher than the impurity concentration of the body region 10, and may be formed in the surface layer portion of the body region 10.

The connection electrode 22 may be arranged on the body region 10 so as to expose the source region 11. The contact region 25 may be formed in the region located directly beneath the connection electrode 22 in the surface layer portion of the body region 10.

According to this structure, in the region outside the connection electrode 22, an occupied area of the contact region 25 can be reduced and an occupied area of the source region 11 can be increased. This configuration is effective in ensuring the connection area of the external electrode with respect to the source region 11. This configuration is also effective in a case where the gate electrodes 17 are to be arranged at a narrow pitch.

In this case, the contact region 25 preferably has the covered portion 26 that is covered by the connection electrode 22, and either one or both of the first lead-out portion 27 and the second lead-out portion 28 that is/are drawn out from the covered portion 26 to the region outside the connection electrode 22. According to this structure, a connection portion of an external electrode with respect to the contact region 25 can be properly secured by either one or both of the first lead-out portion 27 and the second lead-out portion 28.

The semiconductor device 1 may include the source pad electrode 50 (main surface electrode) as the external electrode that is electrically connected to the source region 11 and the contact region 25 on the first main surface 3. The semiconductor device 1 may include the interlayer film 40 that covers the gate electrodes 17 and the connection electrode 22 on the first main surface 3. The semiconductor device 1 may include the source opening 45 that is formed in the interlayer film 40 and exposes the source region 11 and the contact region 25.

In this case, the source pad electrode 50 may be arranged on the interlayer film 40 and is electrically connected to the source region 11 and the contact region 25 inside the source opening 45. According to this structure, an electrical connection portion with respect to the source region 11 and the contact region 25 is properly secured by the interlayer film 40 and the source opening 45.

In another perspective, the semiconductor device 1 may be include the chip 2, the body regions 10, the gate electrodes 17 and the connection electrodes 22. The chip 2 may have the first main surface 3. The body regions 10 may be formed in the surface layer potion of the first main surface 3 at intervals in the first direction X, and may extend in a stripe manner in the second direction Y intersecting the first direction X.

The gate electrodes 17 may be formed on the first main surface 3 at intervals in the first direction X so as to extend between the body regions 10, and may extend in a stripe manner in the second direction Y. The connection electrodes 22 are each formed in regions between the gate electrodes 17 on the first main surface 3, each extend in the first direction X so as to be connected to the gate electrodes 17, and each overlap the corresponding body region 10 in the thickness direction.

According to this structure, the semiconductor device 1 which has a novel structure can be provided. For example, according to the semiconductor device 1, with the connection electrodes 22, the current paths which connect the gate electrodes 17 are formed. Accordingly, the current path is expanded, and thereby a resistance value of an electrode including the gate electrodes 17 and the connection electrodes 22 can be reduced. As a result, switching response characteristics of the semiconductor device 1 can be improved.

The chip 2 may include an SiC. According to this structure, the semiconductor device 1 as an SiC semiconductor device which has a novel structure can be provided. According to the SiC semiconductor device, a withstand voltage can be further enhanced with the physical properties of the SiC. In particular, since the SiC semiconductor device is used in a high-voltage and large-current environment, the reduction in the resistance value (improvement of switching response characteristics) achieved by the connection electrode 22 is also effective in reducing power consumption.

The connection electrodes 22 may be formed in the regions between the gate electrodes 17 at intervals in the second direction Y. According to this structure, a current path of a mesh manner extending in the first direction X and the second direction Y is formed by the gate electrodes 17 and the connection electrodes 22. This reduces the resistance value of the electrode including the gate electrodes 17 and the connection electrodes 22, by the current path of the mesh manner.

The gate electrodes 17 may be formed with the first pitch P1 in the first direction X. The connection electrodes 22 may be formed with the second pitch P2 equal to or greater than the first pitch P1 in the second direction Y. According to this structure, an increase in hidden areas of the body regions 10 covered by the connection electrodes 22 is suppressed, and a decrease in a channel area due to the connection electrode 22 is suppressed. This achieves the effect of reducing the resistance value with the connection electrodes 22 and suppresses an increase in the on-resistance.

The first pitch P1 may be not more than 6 μm. According to this structure, the gate electrodes 17 can be arrayed with a narrow pitch. Thereby, an occupied area of the gate electrodes 17 in the first main surface 3 can be increased. This configuration is effective in reducing the on-resistance while achieving the effect of reducing the resistance value with the connection electrodes 22.

The connection electrodes 22 may each have the width equal to or greater than the width of the gate electrodes 17. According to this structure, current confinements with the connection electrodes 22 are properly suppressed in the regions between the gate electrodes 17. This allows the resistance value to be properly reduced with the connection electrodes 22.

The width of the connection electrodes 22 may be equal to or less than three times the width of the gate electrodes 17. According to this structure, an increase in hidden areas of the body regions 10 covered by the connection electrodes 22 is suppressed, and a decrease in channel areas due to the connection electrodes 22 is suppressed. This achieves the effect of reducing the resistance value with the connection electrode 22 and suppresses an increase in the on-resistance.

The connection electrodes 22 may form a current path including either one or both of a T-shape manner and a cross-shape manner in plan view. According to this structure, the resistance value of the electrode including the gate electrodes 17 and the connection electrodes 22 can be reduced with the current path of a mesh manner including either one or both of a T-shape manner and a cross-shape manner.

The semiconductor device 1 may include the source regions 11 (impurity regions) and the contact regions 25. The source regions 11 may each have the conductivity type different from the conductivity type of the body regions 10, and may each be formed in the surface layer portions of the body regions 10. The contact regions 25 may each have the same conductivity type as the conductivity type of the body regions 10, may each have the impurity concentration higher than the impurity concentration of the body regions 10, and may each be formed in the regions located directly beneath the connection electrodes 22 in the surface layer portions of the body regions 10.

According to this structure, in the regions outside the connection electrodes 22, an occupied area of the contact regions 25 can be reduced and an occupied area of the source regions 11 can be increased. This configuration is effective in ensuring the connection area of the external electrode with respect to the source regions 11. This configuration is also effective in a case where the gate electrodes 17 are to be arranged at a narrow pitch.

In this case, the contact regions 25 preferably each have the covered portion 26 that is covered by the connection electrode 22, and either one or both of the first lead-out portion 27 and the second lead-out portion 28 that is/are drawn out from the covered portion 26 to the region outside the connection electrode 22. According to this structure, connection portions of an external electrode with respect to the contact regions 25 can be properly secured by either one or both of the first lead-out portion 27 and the second lead-out portion 28.

The semiconductor device 1 may include the source pad electrode 50 (main surface electrode) as the external electrode that is electrically connected to the source regions 11 and the contact regions 25 on the first main surface 3. The semiconductor device 1 may include the interlayer film 40 that covers the gate electrodes 17 and the connection electrodes 22 on the first main surface 3. The semiconductor device 1 may include the source openings 45 that are formed in the interlayer film 40 and each expose the corresponding source region 11 and the corresponding contact region 25.

In this case, the source pad electrode 50 may be formed on the interlayer film 40, and is electrically connected to the source regions 11 and the contact regions 25 inside the source openings 45. According to this structure, electrical connection portions with respect to the source regions 11 and the contact regions 25 are properly secured by the interlayer film 40 and the source openings 45.

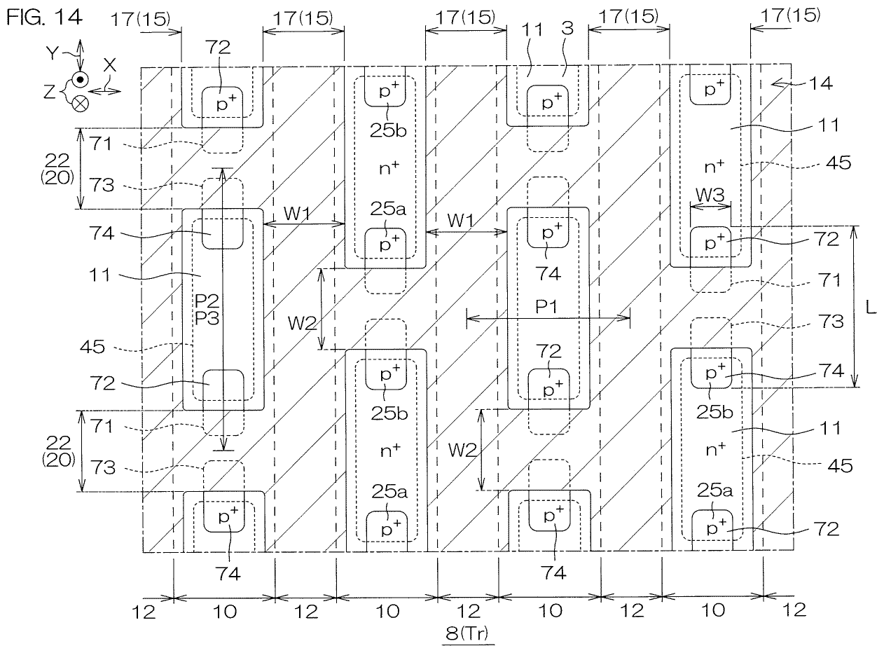

Hereinafter, a first to third modified examples of the semiconductor device 1 shall be described. FIG. 14 is a sectional view illustrating the semiconductor device 1 according to the first modified example. In FIG. 14, although the planar structure 14 according to the first layout example is illustrated, the configuration of the semiconductor device 1 according to a first modified example is also applicable to the second layout example.

The contact regions 25 aforementioned are each formed in the surface layer potion of the corresponding body region 10 so as to face the gate connection structure 20 (the connection electrode 22) in one-to-one correspondence in the thickness direction. However, the contact regions 25 may be formed in the surface layer potion of the corresponding body region 10 so as to face the gate connection structures 20 (the connection electrode 22) in the thickness direction in a one-to-multiple correspondence.

In this case, the contact regions 25 may include a first contact region 25a that is formed on one side of the second direction Y in the region located directly beneath the corresponding gate connection structure 20, and a second contact region 25b that is formed on the other side of the second direction Y in the region located directly beneath the corresponding gate connection structure 20.

The first contact region 25a has a first covered portion 71 and a first lead-out portion 72. The first covered portion 71 consists of a potion that is covered by the corresponding gate connection structure 20. The first lead-out portion 72 consists of a potion that is drawn out from the first covered portion 71 to one side of the second direction Y, and exposed from a region outside the corresponding gate connection structure 20.

The second contact region 25b is formed at an interval from the first contact region 25a to the other side of the second direction Y in a region located directly beneath the corresponding gate connection structure 20, and faces the first contact region 25a across a part of the source region 11.

The second contact region 25b has a second covered portion 73 and a second lead-out portion 74. The second covered portion 73 consists of a portion that is covered by the corresponding gate connection structure 20. The second lead-out portion 74 consists of a portion that is drawn out from the second covered portion 73 to the other side of the second direction Y, and exposed from a region outside the corresponding gate connection structure 20.

The second lead-out portion 74 of the second contact region 25b faces the first lead-out portion 72 of the first contact region 25a in the second direction Y across a part of the source region 11, in a region outside the connection structure 20 (the connection electrode 22).

In this embodiment, the length L of the contact region 25 aforementioned corresponds to a distance in the second direction Y between the first lead-out portion 72 of the first contact region 25a and the second lead-out portion 74 of the second contact region 25b. A lead-out amount in the second direction Y of the first lead-out portion 72 (the second lead-out portion 74) corresponds to the lead-out amount in the second direction Y of the first lead-out portion 27 (the second lead-out portion 28) aforementioned.

In this embodiment, the source openings 45 aforementioned expose the corresponding source region 11, the first lead-out portion 72 of the first contact region 25a, and the second lead-out portion 74 of the second contact region 25b.

The source pad electrode 50 aforementioned is electrically connected to the source regions 11, the first lead-out portions 72 of the first contact regions 25a and the second lead-out portions 74 of the second contact regions 25b inside the source openings 45. That is, the lower electrode film 52 is electrically connected to the source regions 11, the first lead-out portions 72 of the first contact regions 25a and the second lead-out portions 74 of the second contact regions 25b inside the source openings 45.

Also, the embedded electrodes 53 are each electrically connected to the corresponding source region 11, the first lead-out portion 72 of the corresponding first contact region 25a and the second lead-out portion 74 of the corresponding second contact region 25b across the lower electrode film 52 inside the source openings 45. Also, the main electrode film 54 is electrically connected to the source regions 11, the first lead-out portions 72 of the first contact regions 25a and the second lead-out portions 74 of the second contact regions 25b across the lower electrode film 52 and the embedded electrodes 53.

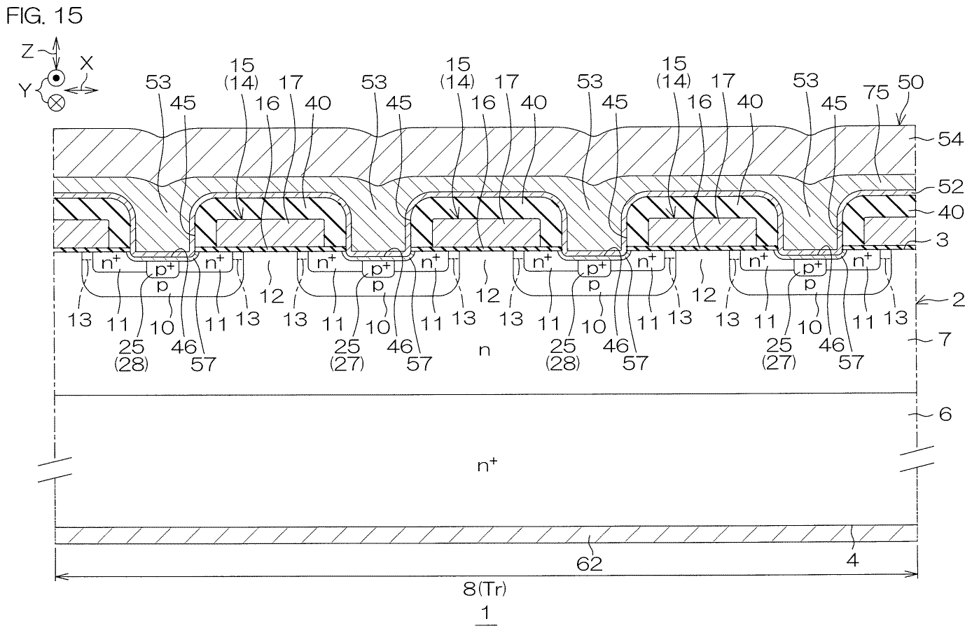

FIG. 15 is a sectional view illustrating the semiconductor device 1 according to the second modified example. The configuration of the semiconductor device 1 according to the second modified example is also applicable to the second layout example. The configuration of the semiconductor device 1 according to the second modified example is also applicable to the first modified example. The source pad electrode 50 aforementioned has the embedded electrodes 53. However, as illustrated in FIG. 15, the source pad electrode 50 may have an intermediate electrode film 75 instead of the embedded electrodes 53.

The intermediate electrode film 75 includes a conductive material different from the conductive material of the lower electrode film 52. The embedded electrodes 53 includes at least one of tungsten, molybdenum, tungsten alloy, and molybdenum alloy. In this embodiment, the embedded electrodes 53 includes tungsten.

The intermediate electrode film 75 directly covers the lower electrode film 52 (the second electrode film 56), and backfills the source openings 45. The intermediate electrode film 75 collectively covers regions of the interlayer film 40 in which the source openings 45 are formed as a film across the lower electrode film 52, and enters into the source openings 45 from on the interlayer film 40.

The intermediate electrode film 75 has a portion that covers the insulating surface of the interlayer film 40 as a film across the lower electrode film 52, and portions that are embedded in the source openings 45 across the lower electrode film 52. The portions of the intermediate electrode film 75 that are embedded in the source openings 45 each correspond to the embedded electrodes 53 aforementioned.

The intermediate electrode film 75 is electrically connected to the source regions 11 and the contact regions 25 via the lower electrode film 52 inside the source openings 45. The intermediate electrode film 75 is electrically connected to the first lead-out portions 27 of the contact regions 25 on one side of the second direction Y and the second lead-out portions 28 of the contact regions 25 on the other side of the second direction Y via the lower electrode film 52 inside the source openings 45.

In this embodiment, the main electrode film 54 directly covers the intermediate electrode film 75. The main electrode film 54 has a portion that covers the insulating surface of the interlayer film 40 across the intermediate electrode film 75, and portions that each cover the source opening 45 across the intermediate electrode film 75. The main electrode film 54 is electrically connected to the source regions 11 and the contact regions 25 across the lower electrode film 52 and the intermediate electrode film 75.

As a matter of course, the source finger electrode 58, the gate pad electrode 60 and the gate finger electrodes 61 may also each have a laminated structure that includes the lower electrode film 52, the intermediate electrode film 75 and the main electrode film 54, as with the case of the source pad electrode 50.

The intermediate electrode film 75 of the source finger electrode 58 enters into the outer openings 47 from on the interlayer film 40, and is electrically connected to the termination region 31 (the overlap region 32) inside the outer openings 47. The main electrode film 54 of the source finger electrode 58 directly covers the intermediate electrode film 75, and is electrically connected to the termination region 31 (the overlap region 32) via the intermediate electrode film 75.

The intermediate electrode film 75 of the gate finger electrodes 61 enters into the gate openings 49 from on the interlayer film 40, and is electrically connected to the gate electrodes 17 and the gate wiring 35 inside the gate openings 49. The main electrode film 54 of the gate finger electrodes 61 directly covers the intermediate electrode film 75, and is electrically connected to the gate electrodes 17 and the gate wiring 35 via the intermediate electrode film 75.

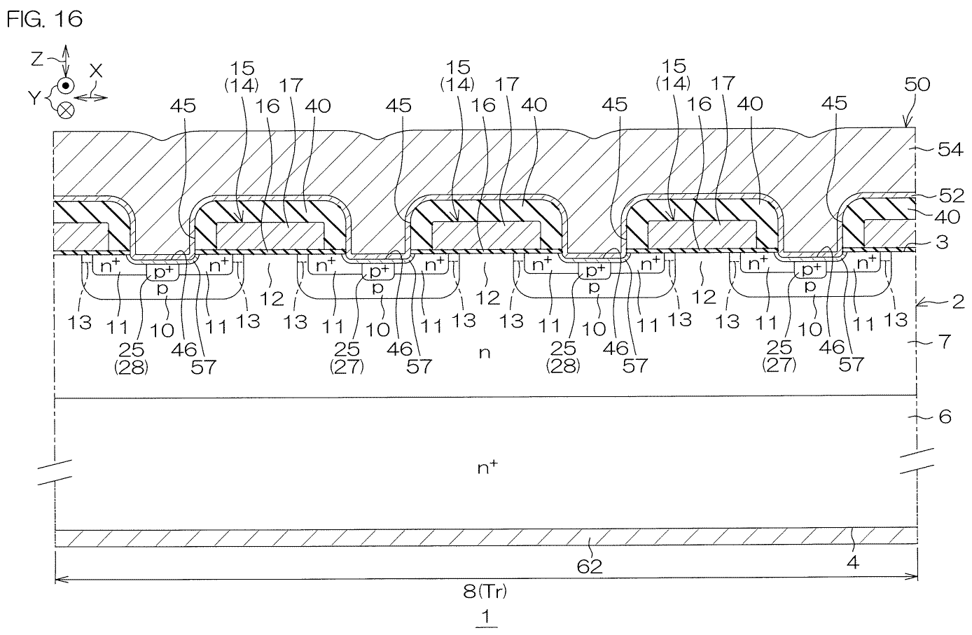

FIG. 16 is a sectional view illustrating the semiconductor device 1 according to the third modified example. The configuration of the semiconductor device 1 according to the third modified example is also applicable to the second layout example. The configuration of the semiconductor device 1 according to the third modified example is also applicable to the first modified example. the source pad electrode 50 aforementioned has the embedded electrodes 53. However, as illustrated in FIG. 16, the source pad electrode 50 may have a laminated structure that does not have the embedded electrode 53, but includes the lower electrode film 52 and the main electrode film 54.

In this embodiment, the main electrode film 54 of the source pad electrode 50 enters into the source openings 45 from on the interlayer film 40, and is electrically connected to the source regions 11 and the contact regions 25 via the lower electrode film 52 inside the source openings 45.

As a matter of course, the source finger electrode 58, the gate pad electrode 60 and the gate finger electrodes 61 may also each have a laminated structure that does not have the embedded electrodes 53, but each include the lower electrode film 52 and the main electrode film 54, as with the case of the source pad electrode 50.

The main electrode film 54 of the source finger electrode 58 enters into the outer openings 47 from on the interlayer film 40, and is electrically connected to the termination region 31 (the overlap region 32) via the lower electrode film 52 inside the outer openings 47. The main electrode film 54 of the gate finger electrodes 61 enters into the gate openings 49 from on the interlayer film 40, and is electrically connected to the gate electrodes 17 and the gate wiring 35 via the lower electrode film 52 inside the gate openings 49.

The above-described embodiments (including modified examples) may be implemented in other modes. For example, in the above-described embodiments, the example where the third gate finger electrode 61c is formed is illustrated. However, the third gate finger electrode 61c does not necessarily have to be formed, and may be omitted. In this case, the notched portion 51 of the source pad electrode 50 may be omitted, and the first pad portion 50a and the second pad portion 50b of the source pad electrode 50 may be integrally formed.

In the above-described embodiments, the chip 2 including the SiC monocrystal is adopted. However, the chip 2 may contain a silicon monocrystal. Similarly, the first semiconductor layer 6 may contain a silicon monocrystal. Similarly, the second semiconductor region 7 may contain a silicon monocrystal.

In the above-described embodiments, a structure may be adopted, in which the conductivity type of the semiconductor region of the “n-type” is inverted to the “p-type,” and the conductivity type of the semiconductor region of the “p-type” is inverted to the “n-type.” A specific arrangement in this case can be obtained by replacing the “n-type” with the “p-type” at the same time as replacing the “p-type” with the “n-type” in the above descriptions and the attached drawings.

In the above-described embodiments, a collector region of the p-type may be formed in the surface layer potion of the second main surface 4 of the chip 2. In this case, the transistor structure Tr includes an IGBT (insulated gate bipolar transistor) structure instead of the MISFET structure A specific configuration in this case is obtained by replacing the “source” of the MISFET structure with an “emitter” of the IGBT structure and replacing the “drain” of the MISFET structure with a “collector” of the IGBT structure in the above descriptions and the attached drawings. In this case, the chip 2 may have a single layer structure consisting of the semiconductor substrate of the n-type.

Hereinafter, examples of features extracted from this Description and the attached drawings shall be indicated. Hereinafter, the alphanumeric characters, etc., in parentheses represent the corresponding components, etc., in the embodiments described above, but are not intended to limit the scope of each clause to the embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.

[A1] A semiconductor device (1), comprising: a chip (2) that has a main surface (3); a body region (10) that is formed in a surface layer portion of the main surface (3); gate electrodes (17) that are arranged on both sides of the body region (10) on the main surface (3); and a connection electrode (22) that is formed in a region between the gate electrodes (17) on the main surface (3) so as to overlap the body region (10) in a thickness direction (Z).

[A2] The semiconductor device (1) according to A1, wherein the chip (2) contains SiC.

[A3] The semiconductor device (1) according to A1 or A2, wherein the body region (10) extends as a band in one direction in plan view, the gate electrodes (17) each extend as a band in the one direction in plan view, and the connection electrode (22) extends as a band in a crossing direction intersecting the one direction in plan view.

[A4] The semiconductor device (1) according to any one of A1 to A3, wherein the connection electrode (22) has a width (W2) equal to or greater than a width (W1) of the gate electrodes (17).

[A5] The semiconductor device (1) according to any one of A1 to A4, wherein the connection electrodes (22) are connected to the gate electrodes (17).

[A6] The semiconductor device (1) according to any one of A1 to A5, further comprising: an impurity region (11) that has a conductivity type (n-type) different from a conductivity type (p-type) of the body region (10), and that is formed in a surface layer portion of the body region (10); and a contact region (25) that has a same conductivity type (p-type) as the conductivity type (p-type) of the body region (10), that has an impurity concentration higher than an impurity concentration of the body region (10), and that is formed in the surface layer portion of the body region (10).

[A7] The semiconductor device (1) according to A6, wherein the connection electrode (22) is arranged on the body region (10) so as to expose the impurity region (11), and the contact region (25) is formed in a region located directly beneath the connection electrode (22) in the surface portion of the body region (10).

[A8] The semiconductor device (1) according to A7, wherein the contact region (25) has a covered portion (26, 71, 73) that is covered by the connection electrode (22), and a lead-out portion (27, 28, 72, 74) that is drawn out from the covered portion (26, 71, 73) to a region outside the connection electrode (22).

[A9] The semiconductor device (1) according to any one of A6 to A8, further comprising: a main surface electrode (50) that is electrically connected to the impurity region (11) and the contact region (25) on the main surface (3).

[A10] The semiconductor device (1) according to A9, further comprising: an interlayer insulating film (40) that covers the gate electrodes (17) and the connection electrode (22) on the main surface (3); and an opening (45) that is formed in the interlayer insulating film (40), and that exposes the impurity region (11) and the contact region (25); and wherein the main surface electrode (50) is arranged on the interlayer insulating film (40), and is electrically connected to the impurity region (11) and the contact region (25) within the opening (45).

[A11] A semiconductor device (1), comprising: a chip (2) that has a main surface (3); body regions (10) that are formed in a surface layer portion of the main surface (3) at intervals in a first direction (X), and extend in a stripe manner in a second direction (Y) intersecting the first direction (X); gate electrodes (17) that are arranged at intervals in the first direction (X) so as to extend between the body regions (10) on the main surface (3), and extend in a stripe manner in the second direction (Y); and connection electrodes (22) that are respectively formed in regions between the gate electrodes (17) on the main surface (3), that respectively extend in the first direction (X) so as to be connected to the gate electrodes (17), and that respectively overlap the corresponding body region (10) in a thickness direction (Z).

[A12] The semiconductor device (1) according to A11, wherein the chip (2) contains SiC.

[A13] The semiconductor device (1) according to A11 or A12, wherein the connection electrodes (22) are arranged in the regions between the gate electrodes (17) at an interval in the second direction (Y).

[A14] The semiconductor device (1) according to A13, wherein the gate electrodes (17) are formed with a first pitch (P1) in the first direction (X), and the connection electrodes (22) are formed with a second pitch (P2) equal to or greater than the first pitch (P1) in the second direction (Y).

[A15] The semiconductor device (1) according to A14, wherein the first pitch (P1) is not more than 6 μm.

[A16] The semiconductor device (1) according to any one of A11 to A15, wherein the connection electrodes (22) each have a width (W2) equal to or greater than a width (W1) of the gate electrodes (17).

[A17] The semiconductor device (1) according to any one of A11 to A16, wherein the connection electrodes (22) form a current path including either one or both of a T-shape manner and a cross-shape manner with the gate electrodes in plan view.

[A18] The semiconductor device (1) according to any one of A11 to A17, further comprising: impurity regions (11) that have a conductivity type (n-type) different from a conductivity type (p-type) of the body regions (10), and are respectively formed in surface layer portions of the body regions (10); and contact regions (25) that have a same conductivity type (p-type) as the conductivity type (p-type) of the body regions (10), that have an impurity concentration higher than an impurity concentration of the body regions (10), and that are formed in regions located directly beneath the connection electrodes (22) in the surface portions of the body regions (10).

[A19] The semiconductor device (1) according to A18, wherein the contact regions (25) each have a covered portion (26, 71, 73) that is covered by the corresponding connection electrode (22), and a lead-out portion (27, 28, 72, 74) that is drawn out from the covered portion (26, 71, 73) to a region outside the corresponding connection electrode (22).

[A20] The semiconductor device (1) according to A19, further comprising: an interlayer insulating film (40) that covers the gate electrodes (17) and the connection electrodes (22) on the main surface (3); and openings (45) that are formed in the interlayer insulating film (40), and expose the corresponding impurity region (11) and the corresponding contact region (25); and embedded electrodes (53) that are respectively embedded in the openings (45), and that are electrically connected to the corresponding impurity region (11) and the corresponding contact region (25).

While specific embodiments have been described in detail above, these are merely specific examples used to clarify the technical contents. The various technical ideas extracted from this description and attached drawings can be combined as appropriate with each other without being limited by the order of description, the order of configuration examples, the order of modification examples, etc., in this description.

What is claimed is:

1. A semiconductor device, comprising:
a chip that has a main surface;
a body region that is formed in a surface layer portion of the main surface;
gate electrodes that are arranged on both sides of the body region on the main surface; and
a connection electrode that is formed in a region between the gate electrodes on the main surface so as to overlap the body region in a thickness direction.

2. The semiconductor device according to claim 1,
wherein the chip includes SiC.

3. The semiconductor device according to claim 1,
wherein the body region extends as a band in one direction in plan view,
the gate electrodes each extend as a band in the one direction in plan view, and
the connection electrode extends as a band in a crossing direction intersecting the one direction in plan view.

4. The semiconductor device according to claim 1,
wherein the connection electrode has a width equal to or greater than a width of the gate electrodes.

5. The semiconductor device according to claim 1,
wherein the connection electrodes are connected to the gate electrodes.

6. The semiconductor device according to claim 1, further comprising:
an impurity region that has a conductivity type different from a conductivity type of the body region, and that is formed in a surface layer portion of the body region; and
a contact region that has a same conductivity type as the conductivity type of the body region, that has an impurity concentration higher than an impurity concentration of the body region, and that is formed in the surface layer portion of the body region.

7. The semiconductor device according to claim 6,
wherein the connection electrode is arranged on the body region so as to expose the impurity region, and
the contact region is formed in a region located directly beneath the connection electrode in the surface portion of the body region.

8. The semiconductor device according to claim 7,
wherein the contact region has a covered portion that is covered by the connection electrode, and a lead-out portion that is drawn out from the covered portion to a region outside the connection electrode.

9. The semiconductor device according to claim 6, further comprising:
a main surface electrode that is electrically connected to the impurity region and the contact region on the main surface.

10. The semiconductor device according to claim 9, further comprising:
an interlayer insulating film that covers the gate electrodes and the connection electrode on the main surface; and
an opening that is formed in the interlayer insulating film, and that exposes the impurity region and the contact region; and
wherein the main surface electrode is arranged on the interlayer insulating film, and is electrically connected to the impurity region and the contact region within the opening.

11. A semiconductor device, comprising:
a chip that has a main surface;
body regions that are formed in a surface layer portion of the main surface at intervals in a first direction X, and extend in a stripe manner in a second direction Y intersecting the first direction;
gate electrodes that are arranged at intervals in the first direction X so as to extend between the body regions on the main surface, and extend in a stripe manner in the second direction Y; and
connection electrodes that are respectively formed in regions between the gate electrodes on the main surface, that respectively extend in the first direction X so as to be connected to the gate electrodes, and that respectively overlap the corresponding body region in a thickness direction.

12. The semiconductor device according to claim 11,
wherein the chip contains SiC.

13. The semiconductor device according to claim 11,
wherein the connection electrodes are arranged in the regions between the gate electrodes at an interval in the second direction Y.

14. The semiconductor device according to claim 13,
wherein the gate electrodes are formed with a first pitch in the first direction X, and
the connection electrodes are formed with a second pitch equal to or greater than the first pitch in the second direction Y.

15. The semiconductor device according to claim 14,
wherein the first pitch is not more than 6 μm.

16. The semiconductor device according to claim 11,
wherein the connection electrodes each have a width equal to or greater than a width of the gate electrodes.

17. The semiconductor device according to claim 11,
wherein the connection electrodes form a current path including either one or both of a T-shape manner and a cross-shape manner with the gate electrodes in plan view.

18. The semiconductor device according to claim 11, further comprising:
impurity regions that have a conductivity type different from a conductivity type of the body regions, and that are respectively formed in surface layer portions of the body regions; and
contact regions that have a same conductivity type as the conductivity type of the body regions, that have an impurity concentration higher than an impurity concentration of the body regions, and that are formed in regions located directly beneath the connection electrodes in the surface portions of the body regions.

19. The semiconductor device according to claim 18,
wherein the contact regions each have a covered portion that is covered by the corresponding connection electrode, and a lead-out portion that is drawn out from the covered portion to a region outside the corresponding connection electrode.

20. The semiconductor device according to claim 19, further comprising:
an interlayer insulating film that covers the gate electrodes and the connection electrodes on the main surface; and
openings that are formed in the interlayer insulating film, and that expose the corresponding impurity region and the corresponding contact region; and
embedded electrodes that are respectively embedded in the openings, and that are electrically connected to the corresponding impurity region and the corresponding contact region.
